(19) United States
(12) Patent Application Publication
(10) Pub. No.: US 2026/0114035 A1
(43) Pub. Date: Apr. 23, 2026

(54) STACKED MULTI-GATE DEVICES HAVING OPTIMIZIED PERFORMANCE

(71) Applicant: Taiwan Semiconductor Manufacturing Company, Ltd., Hsin-Chu (TW)

(72) Inventors: Zhi-Chang Lin, Hsinchu County (TW); Quang Ho Luc, Hsinchu (TW); Ying-Chun Shen, Hsinchu (TW); Chia-Hao Pao, Kaohsiung City (TW); Kian-Long Lim, Hsinchu City (TW); Jui-Lin Chen, Hsinchu (TW); Ping-Wei Wang, Hsinchu (TW); Lu Yang, Hsinchu City (TW)

(21) Appl. No.: 19/039,480

(22) Filed: Jan. 28, 2025

Related U.S. Application Data
(60) Provisional application No. 63/710,914, filed on Oct. 23, 2024.

(51) Int. Cl. H10D 84/85; H10D 64/01; H10D 84/01

(52) U.S. Cl. CPC H10D 84/851; H10D 64/017; H10D 84/017; H10D 84/0184; H10D 84/0188; H10D 84/856

(57) ABSTRACT

Semiconductor devices and methods of forming the same are provided. An exemplary method includes forming a fin over a substrate, a first portion of the fin comprising a plurality of first channel layers interleaved by a plurality of first sacrificial layers, and a second portion of the fin comprising a plurality of second channel layers interleaved by a plurality of second sacrificial layers, forming a trench extending through the fin, laterally recessing the plurality of first sacrificial layers and the plurality of second sacrificial layers at different etch rates, and replacing a remaining portion of the plurality of first sacrificial layers with a first gate structure and replacing a remaining portion of the plurality of second sacrificial layers with a second gate structure.

### PRIORITY DATA

This application claims priority to U.S. Provisional Patent Application Ser. No. 63/710,914, filed Oct. 23, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FETs) where an n-type multi-gate transistor and a p-type multi-gate transistor are stacked vertically, one over the other. While existing C-FETs are generally adequate, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a first method for forming a semiconductor device including a vertical C-FET, according to one or more aspects of the present disclosure.

FIGS. 3, 4, 5, 6, 7, 8, 9, 10, 11, 12A, 12B, 13, 14, 32 illustrate fragmentary cross-sectional views of the semiconductor device during various fabrication stages in the first method of FIG. 2, according to various aspects of the present disclosure.

FIG. 15 illustrates a flow chart of a second method for forming a semiconductor device including a vertical C-FET, according to one or more aspects of the present disclosure.

FIGS. 16, 17, 18, 19, 20 illustrate fragmentary cross-sectional views of the semiconductor device during various fabrication stages in the second method of FIG. 15, according to various aspects of the present disclosure.

FIG. 21 illustrates a flow chart of a third method for forming a semiconductor device including a vertical C-FET, according to one or more aspects of the present disclosure.

FIGS. 22, 23, 24 illustrate fragmentary cross-sectional views of the semiconductor device during various fabrication stages in the third method of FIG. 21, according to various aspects of the present disclosure.

FIG. 25 illustrates a flow chart of a fourth method for forming a semiconductor device including a vertical C-FET, according to one or more aspects of the present disclosure.

FIGS. 26, 27, 28, 29, 30, 31 illustrate fragmentary cross-sectional views of the semiconductor device during various fabrication stages in the fourth method of FIG. 25, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Integrated circuits include a variety of circuit device components, such as transistors. Transistors with different configurations may be suitable for different circuit functions due to their different performance characteristics. A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or GAA transistors. An n-type transistor (e.g., NFET) includes a pair of n-type doped source/drain features, and its majority carrier is electrons. A p-type transistor (PFET) includes a pair of p-type doped source/drain features, and its majority carrier is holes. When the NFET and PFET in a C-FET are fabricated to have same configurations (e.g., same channel sheet thicknesses, same gate lengths), either the PFET or the NFET may not have its corresponding optimal performance. In addition, C-FETs may be configured to achieve different functions (e.g., as a part of a logic cell or as a part of a memory cell) and/or may be used in different applications (e.g., high-performance computing (HPC), or low-current drive). Those different functions or different applications may require the C-FETs exhibiting different aspects of performance (e.g., high-current drive ability, or low power consumption). In some cases, a shorter gate length may lead to a lower channel resistance Rch, which may be beneficial for one aspect of the transistor's performances. However, if the gate length is too short, gate control alibility may not be satisfactory. A thinner channel thickness may lead to a better gate control alibility. However, if the channel thickness is too thin, the channel resistance Rch may be too large. The present disclosure depicts several ways to form C-FETs with different performances by individually adjusting the configurations of the top multi-gate device and the bottom multi-gate device.

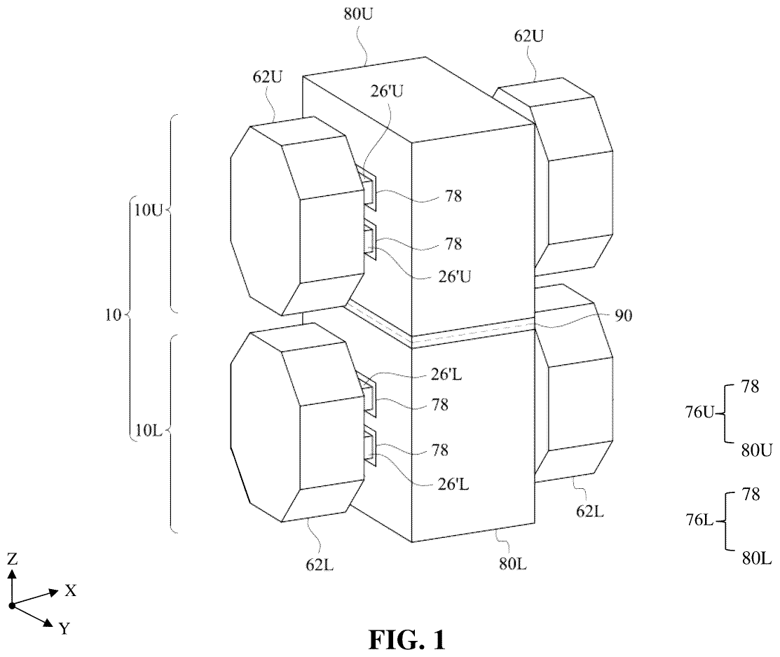

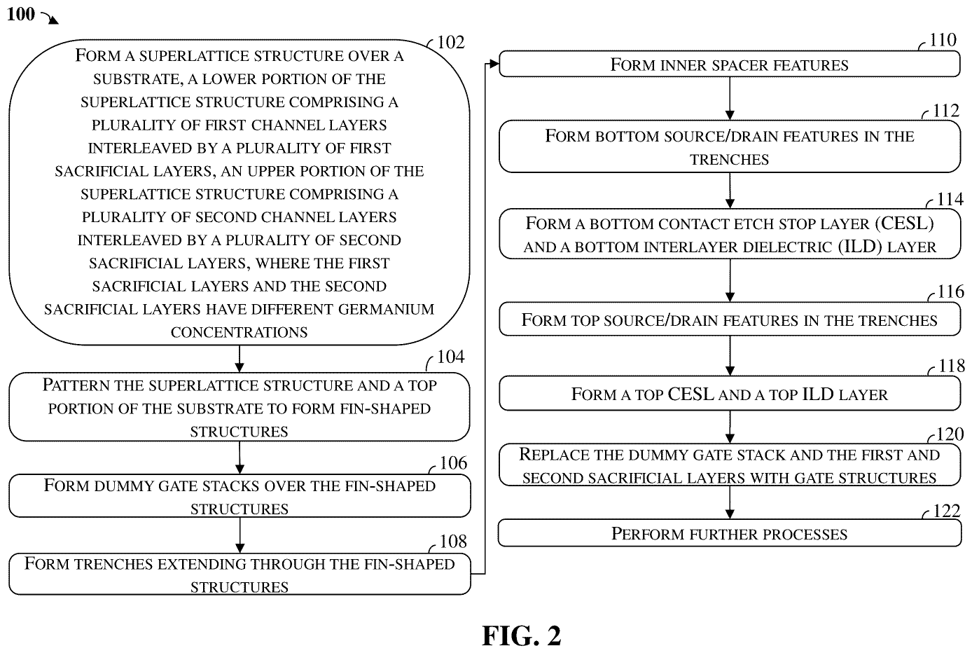

The various aspects of the present disclosure will now be described in more detail with reference to the figures. In that regard, FIG. 1 illustrates a perspective view of a semiconductor device including a vertical C-FET, according to one or more aspects of the present disclosure. FIGS. 2, 15, 21, 25 each illustrate a flow chart of a method for forming a semiconductor device including a vertical C-FET, according to one or more aspects of the present disclosure. Methods represented by FIGS. 2, 15, 21, 25 are merely examples and are not intended to limit the present disclosure to what are explicitly illustrated therein. Additional steps may be provided before, during and after each method, and some steps described can be replaced, eliminated, or moved around for additional embodiments of the method. Not all steps are described herein in detail for reasons of simplicity. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., p-type transistor) and an upper device 10U (e.g., n-type transistor) over the lower device 10L. The lower device 10L includes channel layer 26′L wrapped around by a bottom gate structure 72. The bottom gate structure 72 includes a gate dielectric layer 78 and a gate electrode 80L. The lower device 10L also includes source/drain features (e.g., p-type epitaxial source/drain features) 62L coupled to the channel layers 26′L and adjacent the bottom gate structure 72.

The upper device 10U includes channel layer 26′U wrapped around by an upper gate structure 74. The upper gate structure 74 includes the gate dielectric layer 78 and a gate electrode 80U. The upper device 10U also includes source/drain features (e.g., n-type epitaxial source/drain features) 62U coupled to the channel layers 26′U and adjacent the upper gate structure 74. An isolation layer 90 is disposed between the upper device 10U and the lower device 10L to electrically insulate the upper gate structure 74 of the upper device 10U from the bottom gate structure 72 of the lower device 10L. The configurations of the elements in the semiconductor device 10 described above are given for illustrative purposes and can be modified depending on the actual implementations. It is understood that some features are omitted in this figure for reason of simplicity.

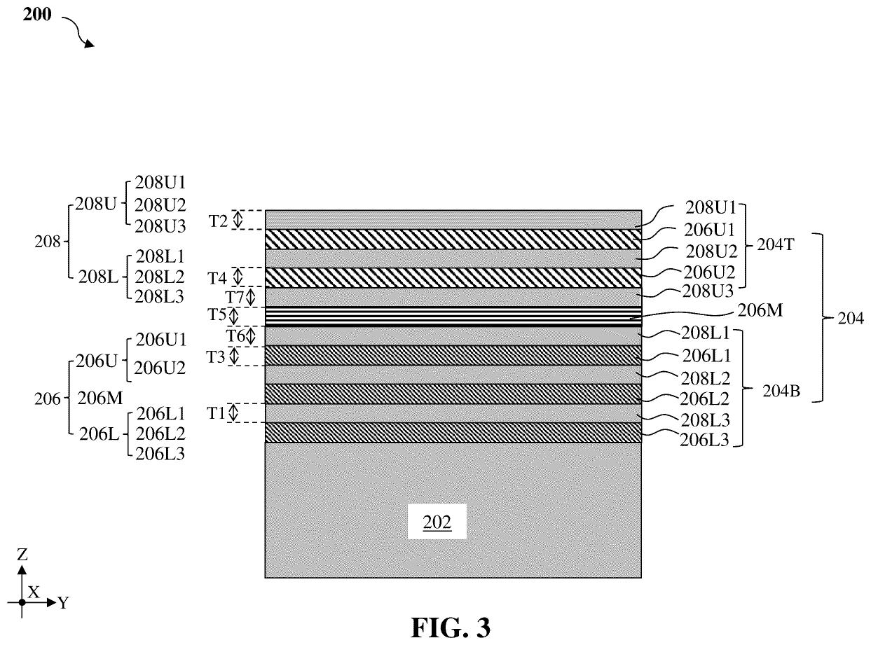

Referring now to FIGS. 2 and 3, method 100 includes a block 102 where a superlattice structure 204 is formed over a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The superlattice structure 204 is formed over the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. For ease of references, the superlattice structure 204 may be vertically divided into a bottom portion 204B, a middle sacrificial layer 206M on the bottom portion 204B, and a top portion 204T on the middle sacrificial layer 206M.

The bottom portion 204B includes a number of first channel layers (e.g., first channel layers 208L1, 208L2, 208L3) interleaved by a number of first sacrificial layers (e.g., first sacrificial layers 206L1, 206L2, 206L3). The first channel layers 208L1, 208L2, 208L3 may be individually or collectively referred to as the first channel layer(s) 208L. The first sacrificial layers 206L1, 206L2, 206L3 may be individually or collectively referred to as the first sacrificial layer(s) 206L. The first sacrificial layers 206L and the first channel layers 208L are deposited alternatingly, one-after-another, to form the bottom portion 204B of the superlattice structure 204. The first sacrificial layers 206L and the first channel layers 208L may have different semiconductor compositions. In some implementations, the first channel layers 208L are formed of silicon (Si) and the first sacrificial layers 206L are formed of silicon germanium (SiGe). In these implementations, the additional germanium content in the first sacrificial layers 206L allow selective removal or recess of the first sacrificial layers 206L without inducing substantial damages to the first channel layers 208L.

The top portion 204T includes a number of second channel layers (e.g., second channel layers 208U1, 208U2, 208U3) interleaved by a number of second sacrificial layers (e.g., second sacrificial layers 206U1, 206U2). The second channel layers 208U1, 208U2, 208U3 may be individually or collectively referred to as the second channel layer(s) 208U. The second sacrificial layers 206U1 and 206U2 may be individually or collectively referred to as the second sacrificial layer(s) 206U. The second sacrificial layers 206U and the second channel layers 208U are deposited alternatingly, one-after-another, to form the top portion of the superlattice structure 204. The second sacrificial layers 206U and the second channel layers 208U may have different semiconductor compositions. In some implementations, the second channel layers 208U are formed of silicon (Si) and the second sacrificial layers 206U are formed of silicon germanium (SiGe). In these implementations, the additional germanium content in the second sacrificial layers 206U allow selective removal or recess of the second sacrificial layers 206U without inducing substantial damages to the second channel layers 208U. The channel layers 208L1, 208L2, 208L3, 208U1, 208U2, and 208U3 will provide nanostructures for the C-FET. In some embodiments, the channel layers 208U1-208U2 will provide channel members for a top GAA transistor of the C-FET, and the channel layers 208L2-208L3 will provide channel members for a bottom GAA transistor in the C-FET. The term “channel member(s)” is used herein to designate any material portion for channel(s) in a transistor with nanoscale dimensions, and having an elongate shape, regardless of the cross-sectional shape of this portion.

In some existing technologies for forming C-FETs, the sacrificial layers 206 have exact the same configurations (e.g., thickness, composition). In this embodiment, to optimize the performance of C-FETs, the second sacrificial layers 206U and the first sacrificial layers 206L are configured to have different germanium concentrations. The germanium concentrations will lead to different etch rates during subsequent etching process, and thus lead to different gate lengths. In this illustrated embodiment, the first sacrificial layers 206L have a first germanium content. In an embodiment, the first germanium content of the first sacrificial layers 206L is between about 5% and about 45%. If the first germanium content is less than 5%, a prolonged etching duration may be applied to remove the first sacrificial layers 206L in a subsequent channel release process, which may damage other features adjacent to the sacrificial layers. Furthermore, a low germanium content may lead to a low etch selectivity between the first sacrificial layers 206L and the first channel layers 208L. That is, the first sacrificial layers 206L may not be selectively removed without substantially etching the first channel layers 208L, leading to a reduced junction overlay region and an increased parasitic resistance. If the first germanium content is greater than 45%, more germanium would diffuse into the first channel layers 208L, increasing an impurity concentration in the first channel layers 208L and degrading the device performance. To achieve the etch rate difference described above, the second sacrificial layers 206U have a second germanium content greater than the first germanium content. In an embodiment, the second germanium content of the second sacrificial layers 206U is between about 10% and about 50%.

In an embodiment, there is also an etch selectivity between the middle sacrificial layer 206M and the first sacrificial layers 206L and an etch selectivity between the middle sacrificial layer 206M and the second sacrificial layers 206U. In an embodiment, the middle sacrificial layer 206M is formed of silicon germanium, and a germanium content of the middle sacrificial layer 206M may be different from the first germanium content and second germanium content of the first and second sacrificial layers 206U and 206L, respectively. In an embodiment, the middle sacrificial layer 206M has a third germanium content greater than the first germanium content and second germanium content. The third germanium content is between about 30% and about 100%. If the third germanium content is less than 30%, the etch selectivity between the middle sacrificial layer 206M and other layers of the superlattice structure 204 may be too low to ensure the complete and selective removal of the middle sacrificial layer 206M without substantially etching the channel layers 208U and 208L.

In some embodiments, a bottommost channel layer 208L3 of the first channel layers 208L has a thickness T1, a topmost channel layer 208U1 of the second channel layers 208U has a thickness T2. Each of the thickness T1 and the thickness T2 is in a range between about 3 nm and about 30 nm. If the thickness T1 or T2 is greater than 30 nm, the aspect ratio of the superlattice structure 204 may be increased, leading to an increased process challenge. In addition, parasitic capacitance related to the semiconductor device 200 may also increase, which would disadvantageously affect the performance of the semiconductor device 200; if the thickness T1 or T2 is less than 3 nm, a reduced thickness of the channel layers 208 (e.g., the first channel layers 208L and/or the second channel layers 208U) may increase the epitaxy difficulty for forming satisfactory layers in the superlattice structure 204. The first sacrificial layers 206L each have a thickness T3, the second sacrificial layers 206U each have a thickness T4. Each of the thickness T3 and the thickness T4 is in a range between about 2 nm and about 30 nm. If the thickness T3 or T4 is greater than 30 nm, the aspect ratio of the superlattice structure 204 may be increased, leading to an increased process challenge. In addition, parasitic capacitance related to the semiconductor device 200 may also increase, which would disadvantageously affect the performance of the semiconductor device 200; if the thickness T3 or T4 is less than 2 nm, a reduced thickness of the sacrificial layers 206 (e.g., the first sacrificial layers 206L and/or the second sacrificial layers 206U) may reduce the process window for forming satisfactory gate structures wrapping around nanostructures. The middle sacrificial layer 206M has a thickness T5. The thickness T5 is in a range between about 2 nm and about 30 nm. If the thickness T5 is greater than 30 nm, the aspect ratio of the superlattice structure 204 may be increased, leading to an increased process challenge; if the thickness T5 is less than 2 nm, a reduced thickness of the middle sacrificial layer 206M may reduce the process window for forming an isolation layer disposed between the gate structure of the upper device and the gate structure of the lower device. In this illustrated embodiments, the topmost channel layer 208L1 of the first channel layers 208L and the bottommost channel layer 208U3 of the second channel layers 208U are in direct contact with the middle sacrificial layer 206M and will be released to form nanostructures 2080N1 and 2080N2 during subsequent fabrication processes. The topmost channel layer 208L1 has a thickness T6. The bottommost channel layer 208U3 has a thickness T7. The thickness T6 and the thickness T7 may be less than the thickness T1. In an embodiment, each of the thickness T6 and the thickness T7 is less than about 10 nm (e.g., 0≤T6≤10 nm; 0≤T7≤10 nm). If the thickness T6 or T7 is greater than 10 nm, the aspect ratio of the superlattice structure 204 may be increased, leading to an increased process challenge. In addition, parasitic capacitance related to the semiconductor device 200 may also increase, which would disadvantageously affect the performance of the semiconductor device 200.

It is noted that the superlattice structure 204 in FIG. 3 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed within the bottom portion 204B and the top portion 204T. The number of layers depends on the desired number of channels members for the top GAA transistor and the bottom GAA transistor. In some embodiments, the number of the channel layers 208 in the superlattice structure 204 may be between 2 and 10.

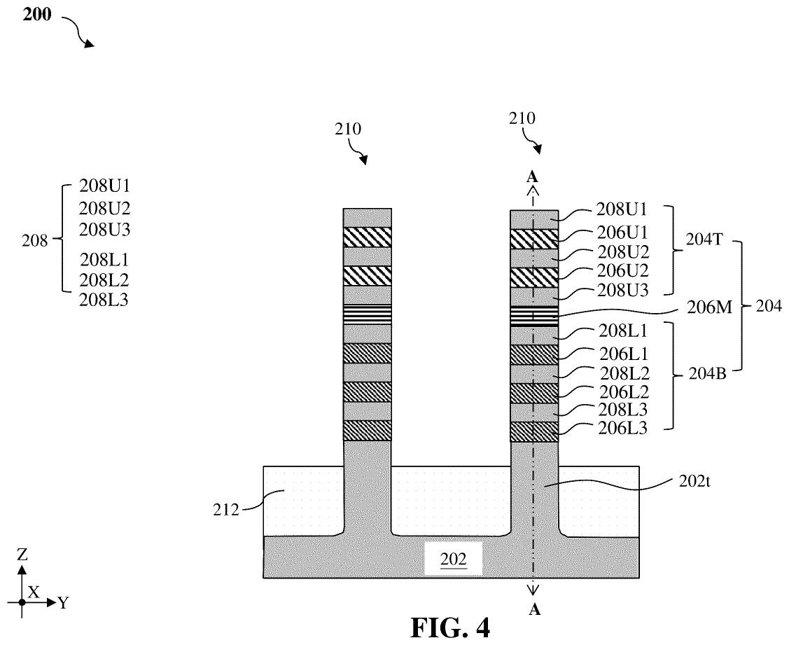

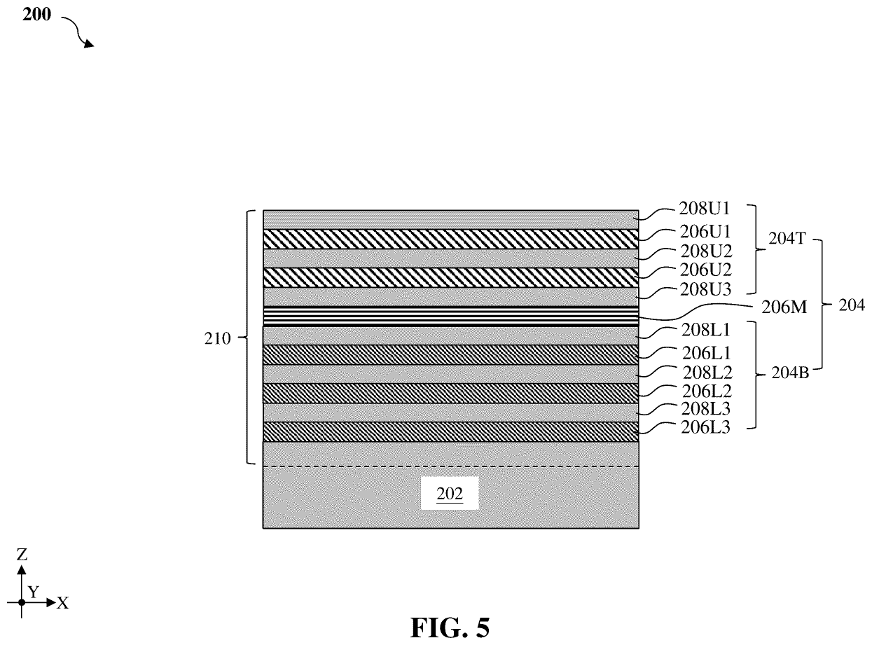

Referring now to FIGS. 4 and 5, method 100 includes a block 104 where the superlattice structure 204 and a top portion 202t of the substrate 202 are patterned to form fin-shaped structures 210. FIG. 4 depicts a cross-sectional view of the intermediate structure 200, and FIG. 5 depicts a cross-sectional view of the intermediate structure 200 taken along line A-A shown in FIG. 4. After forming the superlattice structure 204, the superlattice structure 204 and the top portion 202t are then patterned to form the fin-shaped structures 210. The patterned portion of the substrate 202 may be referred to as a protrusion 202t, a mesa 202t, or a base fin 202t. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 4-5, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The intermediate structure 200 also includes an isolation feature 212 (shown in FIG. 4) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, subatmospheric CVD (SACVD), flowable CVD, spin-on coating, and/or other suitable process. Then, the deposited dielectric material is planarized and recessed to form the isolation feature 212. As shown in FIG. 4, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

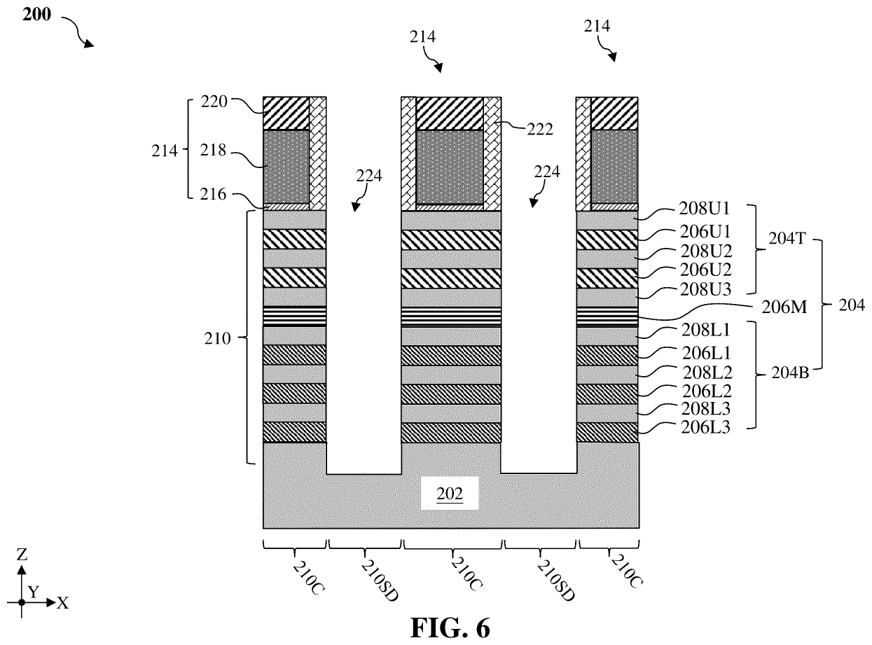

Referring to FIGS. 2 and 6, method 100 includes a block 106 where dummy gate stacks 214 are formed over channel regions 210C of the fin-shaped structure 210. In some embodiments, a gate replacement process (or gate-last process) is adopted where the dummy gate stack 214 serves as a placeholder for a functional gate structure. Other processes and configurations are possible. To form the dummy gate stack 214, a dummy dielectric layer 216, a dummy gate electrode layer 218, and a gate-top hard mask layer 220 are deposited over the intermediate structure 200. The deposition of these layers may include use of chemical vapor deposition (CVD), low-pressure CVD (LPCVD), plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer structure that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stack 214. The dummy gate stack 214 extends lengthwise along the Y direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source and/or a drain region for forming a drain, individually or collectively dependent upon the context.

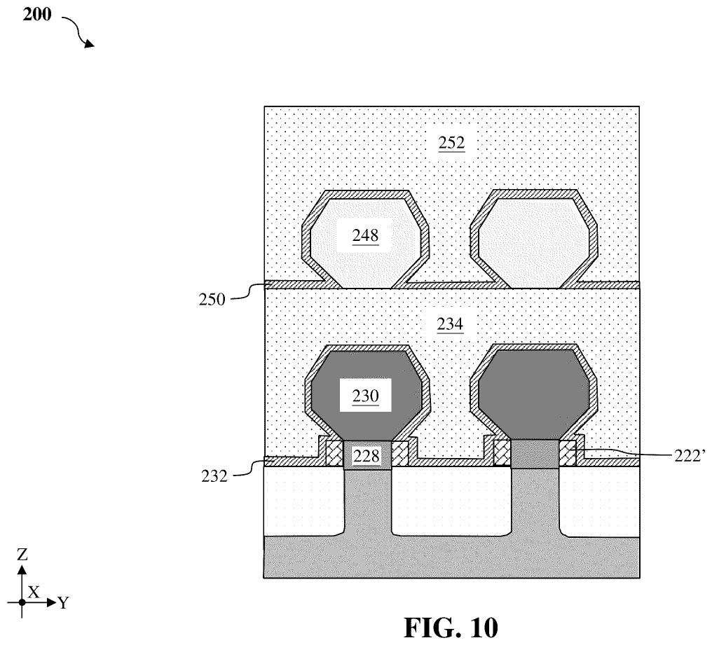

Still referring to FIGS. 2 and 6, method 100 includes a block 108 where source/drain regions 210SD of the fin-shaped structure 210 are recessed to form trenches 224. Operations at block 108 may include formation of at least one gate spacer 222 over the sidewalls of the dummy gate stack 214 before the source/drain regions 210SD are recessed. In some embodiments, the formation of the at least one gate spacer 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. In some embodiments, fin sidewall spacers 222′ (shown in FIG. 10) may also be formed along with the gate spacer 222. The fin sidewall spacers 222′ and the gate spacer 222 have a same composition. After the formation of the gate spacer 222, an anisotropic etch process is performed to the intermediate structure 200 to form the trenches 224. The etch process at block 108 may be a dry etch process or other suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 6, sidewalls of the sacrificial layers 206 and the channel layers 208 in the channel regions 210C are exposed in the trenches 224. In an embodiment, the trenches 224 have substantially straight sidewalls. That is, after forming the trenches 224, the channel layers 208 and the sacrificial layers 206 may have a substantially uniform width.

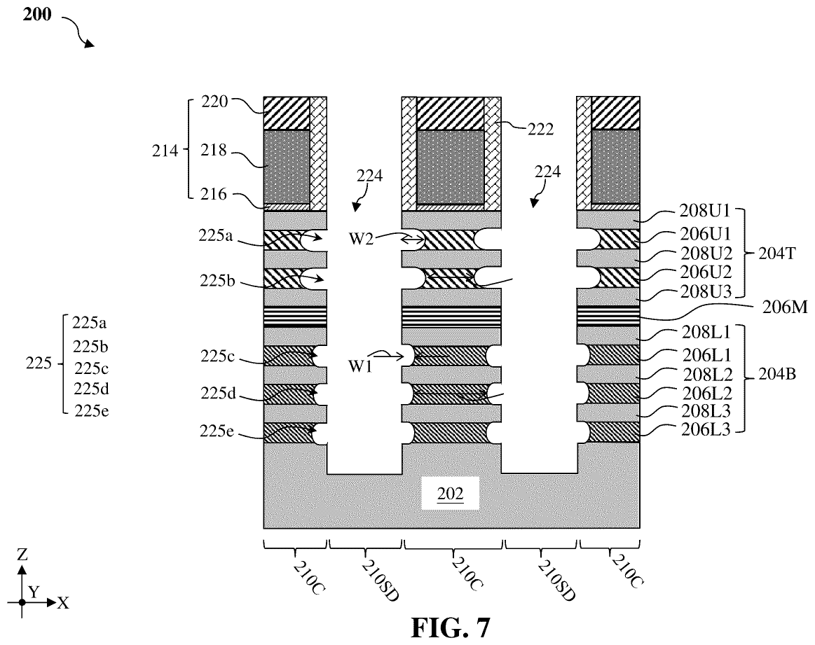

Referring to FIGS. 2 and 7-8, method 100 includes a block 110 where inner spacer features 226 are formed. With reference to FIG. 7, at block 110, an etching process is performed to selectively and partially recess the sacrificial layers 206 exposed in the trenches 224 to form inner spacer recesses 225 without substantially etching the exposed channel layers 208. In this embodiment, the second sacrificial layers 206U have the second germanium content greater than the first germanium content of the first sacrificial layers 206L, and an etchant of the etching process etches the second sacrificial layers 206U at a rate higher than it etches the first sacrificial layers 206L. In some embodiments, the etching process may be a selective isotropic etching process (e.g., a selective dry etching process or a selective wet etching process), and the extent at which the first sacrificial layers 206L and second sacrificial layers 206U are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). In this illustrated embodiment, the inner spacer recesses 225 include an inner spacer recess 225a disposed between the channel layers 208U1 and 208U2, an inner spacer recess 225b disposed between the channel layers 208U2 and 208U3, an inner spacer recess 225c disposed between the channel layers 208L1 and 208L2, an inner spacer recess 225d disposed between the channel layers 208L2 and 208L3, and an inner spacer recess 225e disposed between the channel layer 208L3 and the substrate 202. The inner spacer recesses 225a and 225b are formed over the middle sacrificial layer 206M, and the inner spacer recesses 225c, 225d, and 225e are formed under the middle sacrificial layer 206M. Upon completion of the etching process, the inner spacer recess 225c/225d/225e spans a first width W1, the inner spacer recess 225a/225b spans a second width W2 greater than the width W1. Similarly, the recessed first sacrificial layer 206L has a width greater than a width of the recessed second sacrificial layer 206U.

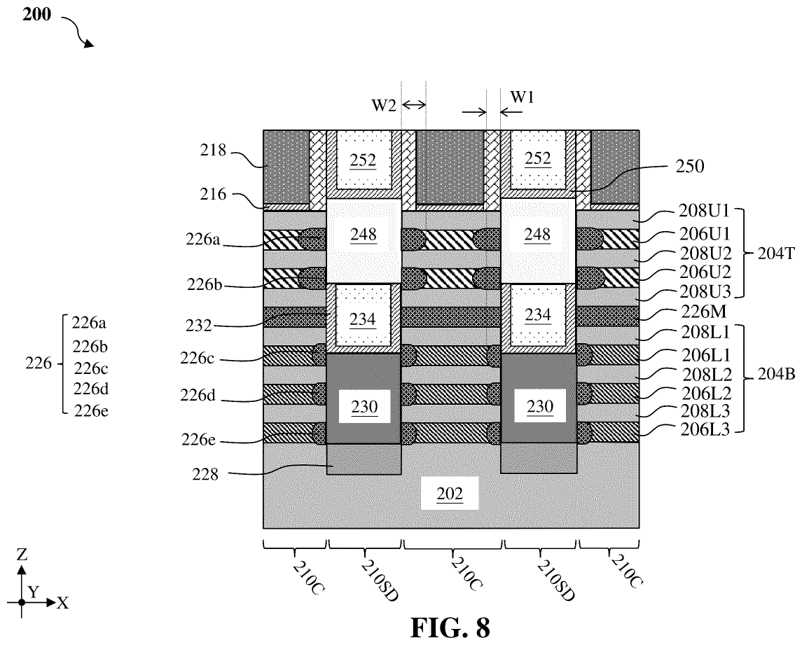

With reference to FIG. 8, after the formation of the inner spacer recesses 225, an inner spacer material layer is deposited over the intermediate structure 200, including in the inner spacer recesses 225. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacer 222, and sidewalls of the channel layers 208, thereby forming the inner spacer features 226 shown in FIG. 8. The inner spacer features 226 track the shape of the inner spacer recesses 225. In the present embodiments, the inner spacer features 226 includes an inner spacer feature 226a formed in the inner spacer recess 225a, an inner spacer feature 226b formed in the inner spacer recess 225b, an inner spacer feature 226c formed in the inner spacer recess 225c, an inner spacer feature 226d formed in the inner spacer recess 225d, and an inner spacer feature 226e formed in the inner spacer recess 225e. The inner spacer feature 226a/226b has the width W2, and the inner spacer features 226c/226d/226e has the width W1 less than the width W2.

As represented by FIG. 7 and FIG. 8, the middle sacrificial layer 206M is also replaced by a middle dielectric layer 226M. In this illustrated embodiment, the middle sacrificial layer 206M remains unetched during the formation of the inner spacer recesses 225. This may be achieved by selectively forming an inhibitor layer covering the exposed sidewalls of the middle sacrificial layer 206M. The inhibitor layer may be removed after the forming of the inner spacer features 226. Another etching process may be then performed to selectively remove the middle sacrificial layer 206M. A dielectric material may be then deposited in the space left behind by selective removal of the middle sacrificial layer 206M, thereby forming the middle dielectric layer 226M. The middle dielectric layer 226M and the inner spacer features 226 may have a same composition or may be formed of different compositions. In some alternative embodiments, during the formation of the inner spacer recesses 225, there is no inhibitor layer being formed to cover the exposed sidewalls of the middle sacrificial layer 206M. The middle sacrificial layer 206M, due to its greater germanium content, may be substantially removed during the formation of inner spacer recesses 225. The inner spacer material layer may also be deposited in the space left behind by selective removal of the middle sacrificial layer 206M, thereby forming the middle dielectric layer 226M.

Still referring to FIGS. 2 and 8, method 100 includes a block 112 where bottom source/drain features 230 are formed in the trenches 224. In some embodiments, before the deposition of the bottom source/drain features 230, a blocking layer (not shown) may be deposited over the intermediate structure 200 to cover sidewalls of the top portion 204T of the superlattice structure 204. The blocking layer may also cover sidewalls of the middle dielectric layer 226M and the channel layer 208L1. The blocking layer may include dielectric materials. After the formation of the blocking layer, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208 not covered by the blocking layer. In the present embodiments, the epitaxial growth of bottom source/drain features 230 may take place from both the top surface of the substrate 202 and the exposed sidewalls of the channel layers 208L2 and 208L3. The blocking layer, due to its dielectric composition, blocks formation of the bottom source/drain features 230 on sidewalls of the channel layers 208U1-208U3 and 208L1. As illustrated in FIG. 8, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some cases, before forming the bottom source/drain features 230 in the trenches 224, an undoped semiconductor layer 228 (e.g., undoped silicon or undoped silicon germanium) may be formed to fill a bottom portion of the trenches 224.

Still referring to FIGS. 2 and 8, method 100 includes a block 114 where a bottom contact etch stop layer (CESL) 232 and a bottom interlayer dielectric (ILD) layer 234 are formed over the bottom source/drain features 230. The bottom CESL 232 may include silicon nitride, silicon oxycarbonitride, and/or other materials and may be formed by CVD, ALD, plasma-enhanced chemical vapor deposition (PECVD) process and/or other suitable deposition or oxidation processes. In an embodiment, the bottom CESL 232 includes silicon nitride. In some embodiments, the bottom CESL 232 is first conformally deposited on the intermediate structure 200 and the bottom ILD layer 234 is deposited over the bottom CESL 232 by spin-on coating, flowable CVD (FCVD), CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The bottom CESL 232 and the bottom ILD layer 234 may be etched back to exposed sidewalls of the channel layers 208U1 and 208U2. In embodiments presented by FIG. 8, after being etched back, the bottom CESL 232 is in direct contact with the inner spacer features 226b-226c, the channel layers 208U3 and 208L1, and the middle dielectric layer 226M. The blocking layer may be removed during the etch back of the bottom CESL 232 and the bottom ILD layer 234.

Still referring to FIGS. 2 and 8, method 100 includes a block 116 where top source/drain features 248 are formed over the bottom CESL 232 and the bottom ILD layer 234. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. In some embodiments, before forming the top source/drain features 248, another dielectric layer (e.g., silicon nitride) may be formed over the bottom CESL 232 and the bottom ILD layer 234. This another dielectric layer may be vertically sandwiched by the top source/drain features 248 and the bottom CESL 232 and the bottom ILD layer 234.

Still referring to FIGS. 2 and 8, method 100 includes a block 118 where a top CESL 250 and a top ILD layer 252 are deposited over the top source/drain features 248. The top CESL 250 may include silicon nitride, silicon oxycarbonitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the intermediate structure 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the intermediate structure 200 may be annealed to improve integrity of the top ILD layer 252. To remove excess materials and to expose top surfaces of the dummy gate electrode layers 218, a planarization process, such a chemical mechanical polishing (CMP) process may be performed.

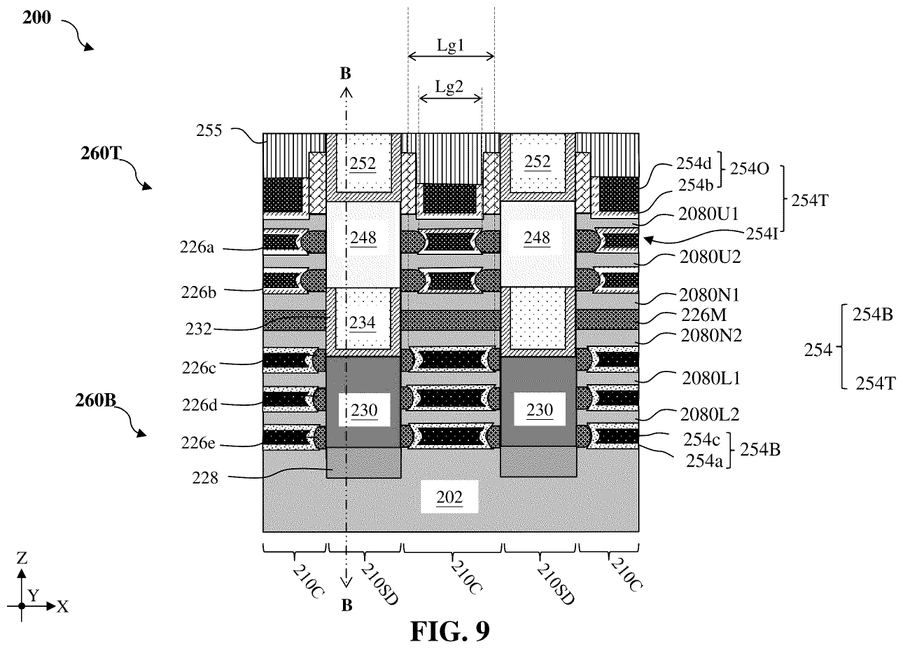

Referring now to FIGS. 2 and 9-10, method 100 includes a block 120 where the dummy gate stack 214 and the sacrificial layers 206 are replaced by gate structures. FIG. 10 depicts a fragmentary cross-sectional view of the intermediate structure 200 taken along line B-B shown in FIG. 9. Operations at block 120 may include removal of the dummy gate stacks 214, release of the channel layers 208 as channel members (including top channel members 2080U1, 2080U2, and bottom channel members 2080L1, and 2080L2) and nanostructures (including the nanostructures 2080N1 and 2080N2). The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. The selective removal of the dummy gate stacks 214 forms gate trenches (now filled by an outer portion 254O of the top gate structures 254T).

After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the top channel members 2080U1, 2080U2, the bottom channel members 2080L1, and 2080L2) and nanostructures (including the nanostructures 2080N1 and 2080N2). In embodiments represented by FIG. 9, the top channel members 2080U1 and 2080U2 are in direct contact with the top source/drain features 248; the bottom channel members 2080L1 and 2080L2 are in direct contact with the bottom source/drain features 230; and the nanostructures 2080N1, 2080N2 and the middle dielectric layer 226M are in direct contact with the bottom CESL 232.

The selective removal of the first sacrificial layers 206L forms first gate openings (now filled by the bottom gate structures 254B), and the selective removal of the second sacrificial layers 206U forms second gate openings (now filled by an inner portion 254I of the top gate structures 254T). The first gate openings spans a width greater than a width of the second gate openings. The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

The bottom gate structure 254B is then formed in the first gate opening and adjacent to the bottom source/drain features 230 and the top gate structure 254T is formed in the second gate opening and adjacent to the top source/drain features 248 and in the gate trench. The bottom gate structure 254B and the top gate structure 254T may be individually or collectively referred to as a gate structure 254. The bottom gate structure 254B is formed to wrap around each of the bottom channel members 2080L1 and 2080L2, thereby forming a bottom multi-gate transistor 260B (e.g., similar to the device 10L in FIG. 1), and the top gate structure 254T is formed to wrap around each of the top channel members 2080U1 and 2080U2, thereby forming a top multi-gate transistor 260T (e.g., similar to the device 10U in FIG. 1) disposed over the bottom multi-gate transistor 260B.

The formation of the bottom gate structure 254B and top gate structure 254T includes forming a bottom gate dielectric layer 254a surrounding the channel members 2080L1 and 2080L2 and a top gate dielectric layer 254b surrounding the channel members 2080U1 and 2080U2. In an embodiment, the bottom gate dielectric layer 254a and the top gate dielectric layer 254b are formed simultaneously and have a same composition. For example, each of the bottom gate dielectric layer 254a and the top gate dielectric layer 254b includes an interfacial layer (not separately labeled) and a high-K dielectric layer (not separately labeled) over the interfacial layer. The interfacial layer may be formed over the channel members 2080U1-2080U2, 2080L1-2080L2, and the nanostructures 2080N1-2080N2, and cover top and sidewall surfaces of protrusions 202t. The interfacial layer may be formed by thermal oxidation, chemical oxidation, atomic layer deposition (ALD), chemical vapor deposition (CVD), other suitable process, or a combination thereof. For embodiments in which the interfacial layer is formed by thermal oxidation, the interfacial layer forms on semiconductor surfaces (e.g., channel members 2080U1-2080U2, 2080L1-2080L2, and the nanostructures 2080N1-2080N2), but not dielectric surfaces (e.g., isolation features 212). In some other embodiments, the interfacial layer may be conformally deposited over the substrate 202, including on the isolation features 212. The interfacial layer includes a dielectric material, such as SiO₂, SiGeOx, HfSiO, SiON, other dielectric material, or a combination thereof. In some embodiments, the interfacial layer is group IV-based oxide layers, which generally refer to oxides of a group IV-based material (i.e., a material that includes at least one group IV element, such as Si, Ge, C, etc.). In some embodiments, the interfacial layer is group III-V-based oxide layers, which generally refer to oxides of a group III-V-based material (i.e., a material that includes at least one group III element, such as Al, Ga, In, B, etc., and at least one group V element, such as N, P, As, Sb, etc.). The high-K dielectric layer may include dielectric materials having a high dielectric constant, for example, greater than a dielectric constant of silicon oxide. Exemplary high-K dielectric materials include hafnium, zirconium, tantalum, titanium, oxygen, nitrogen, other suitable constituent, or combinations thereof. In some implementations, the high-K dielectric layer may include a high-K dielectric material including, for example, HfO₂, HfSiO, HfSiON, HfTaO, HfTiO, HfZrO, ZrO₂, TiO₂, Ta₂O₅, other suitable high-K dielectric material, or combinations thereof. The formation of the bottom gate structure 254B and top gate structure 254T also includes forming a bottom gate electrode 254c for the bottom gate structure 254B and a top gate electrode 254d for the top gate structure 254T. Each of the bottom and top gate electrodes 254c-254d may include one or more work function layers with proper work functions such that the corresponding transistor is enhanced for its device performance (for example, reduced threshold voltage).

For embodiments in which the bottom multi-gate transistor 260B is a p-type transistor and the top multi-gate transistor 260T is an n-type transistor, the bottom gate electrode 254c includes a p-type work function layer, and the top gate electrode 254d includes an n-type work function layer. The n-type work function layer may include titanium-aluminum based metal, such as titanium aluminum carbon (TiAlC) or titanium aluminum (TiAl). The P-type work function layer may include titanium nitride (TiN), tungsten carbonitride (WCN), tantalum nitride (TaN), or molybdenum nitride (MoN). The gate electrode 254c/254d may also include a metal fill layer including aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof.

The bottom gate structure 254B has a first gate length Lg1 along the X direction, and the inner portion 254I of the top gate structure 254T has a second gate length Lg2 less than the first gate length Lg1. In an embodiment, a ratio of the second gate length Lg2 to the first gate length Lg1 is greater than 0.3 and less than 1. If the ratio is less than 0.3, then the inner portion 254I of the top gate structure 254T may be too short, leading to weak gate control and increased leakage current. By forming gate structures with different gate lengths (Lg1, Lg2), performances of the top multi-gate transistor 260T and the bottom multi-gate transistor 260B may be adjusted. In general, performance of the transistor having a longer gate length may be weak than the performance of the transistor having a shorter gate length. In an embodiment, the bottom multi-gate transistor 260B is a p-type transistor and the top multi-gate transistor 260T is an n-type transistor, and the performance of the bottom multi-gate transistor 260B is weaker than the performance of the top multi-gate transistor 260T.

Still Referring to FIGS. 2 and 9, method 100 includes a block 122 where further processes are performed to complete the fabrication of the semiconductor device 200. Such further processes may include forming a dielectric capping layer 255 over the top gate structure 254T. Such further processes may also include forming a silicide layer over the top source/drain features and forming a multi-layer interconnect (MLI) structure over the intermediate structure 200. The MLI may include various interconnect features, such as vias and conductive lines, disposed in dielectric layers, such as etch-stop layers and ILD layers. In some embodiments, the vias are vertical interconnect features configured to interconnect device-level contacts, such as source/drain contacts formed over the top source/drain features 248. Other processes may be further performed.

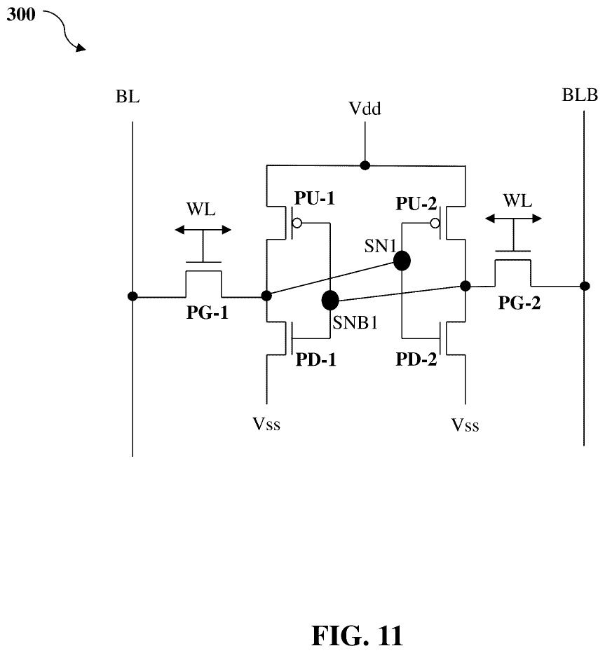

The method 100 may be applied to form an IC structure 300 with improved performance (e.g., enhanced speed, reduced power consumption, or reduced performance gap between NFETs and PFETs). For example, the semiconductor device 200 is a part of the IC structure 300. With reference to FIGS. 11, 12A-12B, and 13, the IC structure 300 includes at least an array of memory cells. The array may include static random-access memory (SRAM) cells, dynamic random-access memory (DRAM) cells, non-volatile random-access memory (NVRAM) cells, flash memory cells, other suitable memory cells, or combinations thereof. In an embodiment, the array includes a number of SRAM cells, which generally provide memory or storage capable of retaining data when power is applied. In the present embodiments, each SRAM cell includes one or more C-FETs 200 described above.

FIG. 11 illustrates an exemplary circuit schematic for a single-port SRAM cell (e.g., 1-bit SRAM cell). The single-port SRAM cell includes pull-up transistors PU-1, PU-2; pull-down transistors PD-1, PD-2; and pass-gate transistors PG-1, PG-2. As show in the circuit diagram, transistors PU-1 and PU-2 are P-type transistors, and transistors PG-1, PG-2, PD-1, and PD-2 are N-type transistors. The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a first data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to power voltage Vdd, and the sources of the pull-down transistors PD-1 and PD-2 are coupled to a voltage Vss, which may be an electrical ground in some embodiments. The first storage node SN1 of the first data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL. In this embodiment, p-type transistors (e.g., PU-1, PU-2) have a gate length greater than a gate length of the n-type transistors (e.g., PD-1, PD-2, PG-1, PG-2).

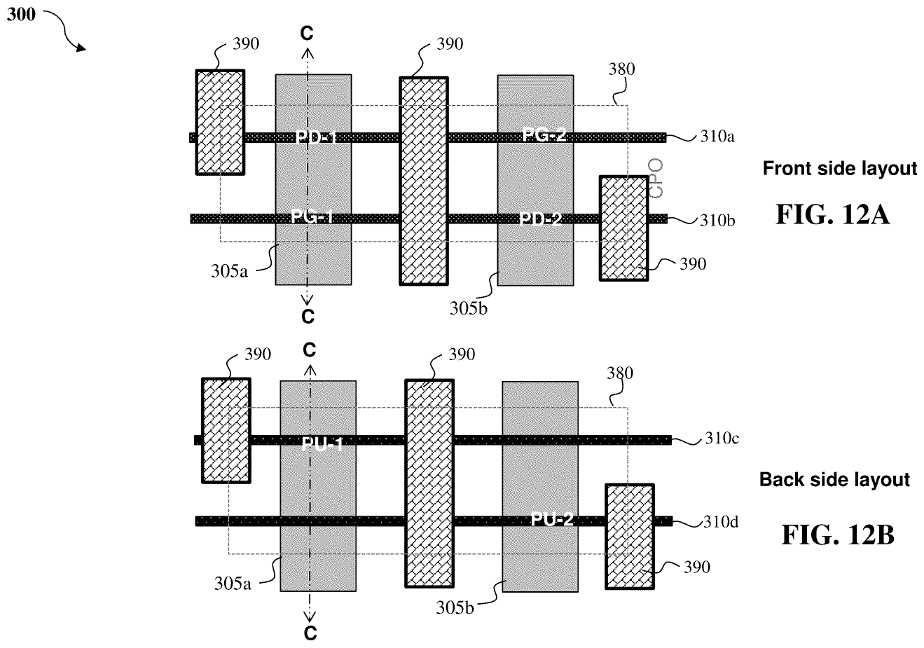

In this embodiment, the SRAM cell is C-FET based SRAM cell. FIG. 12A illustrates a fragmentary front side layout of the SRAM cell of the IC structure 300, FIG. 12B illustrates a fragmentary back side layout of the SRAM cell of the IC structure 300. The SRAM cell includes active regions 305a each disposed in a p-type doped region and active regions 305b each disposed in an n-type doped region. The active regions 305a and active regions 305b may be similar to the active regions 210 after the channel release process. The SRAM cell of the IC structure 300 includes gate structures 310a, 310b, 310c, and 310d wrapping around channel regions of the active regions 305a and 305b to various transistors such as pull-down transistors PD-1 and PD-2, pull-up transistors PU-1 and PU-2, and pass-gate transistors PG-1 and PG-2. The gate structure 310a and the active region 305a form a part of the pull-down transistor PD-1, the gate structure 310b and the active region 305a form a part of the pass-gate transistor PG-1, the gate structure 310a and the active region 305b form a part of the pass-gate transistor PG-2, and the gate structure 310b and the active region 305b form a part of the pull-down transistor PD-2. The gate structure 310c and the active region 305a form a part of the pull-up transistor PU-1, the gate structure 310d and the active region 305b form a part of the pull-up transistor PU-2. Each of the gate structures 310a and 310b may be similar to the top gate structure 254T, and each of the gate structures 310c and 310d may be similar to the bottom gate structure 254B. The SRAM cell has a cell 380. The IC structure 300 also includes a number of gate isolation features 390 configured to cut at least one of the gate structures 310a-310d into physically and electrically isolated pieces.

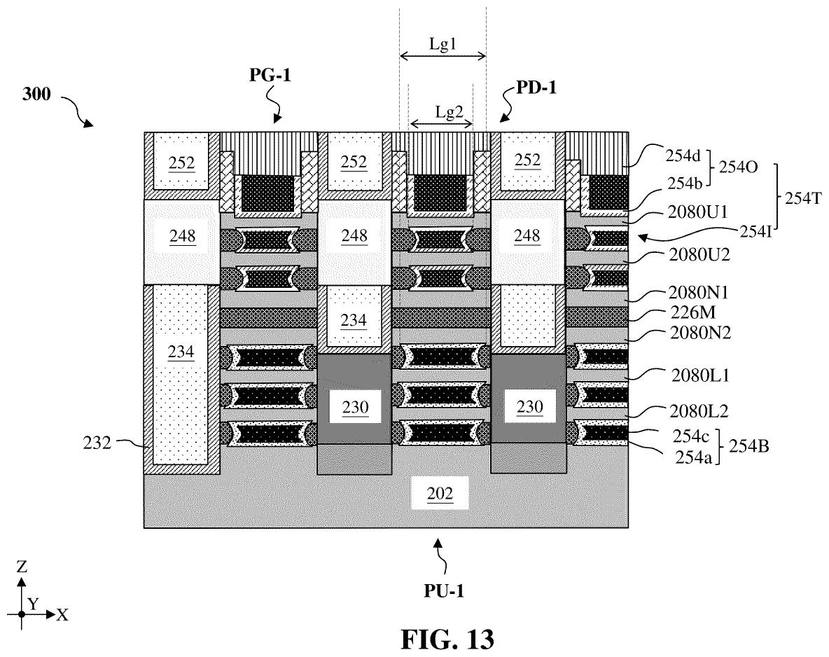

FIG. 13 depicts a fragmentary cross-sectional view of the SRAM cell of the IC structure 300 taken along line C-C shown in FIGS. 12A-12B. As represented by FIG. 13, the pull-down transistor PD-1 is formed over the pull-up transistor PU-1. The pull-down transistor PD-1 and the pass-gate transistor PG-1 are similar to the top multi-gate transistor 260T, and the pull-up transistor PU-1 is similar to the bottom multi-gate transistor 260B. That is, a gate length of the pass-gate transistor PG-1 and pull-down transistor PD-1 is less than a gate length of pull-up transistor PU-1.

By reducing gate lengths of the pass-gate transistors PG-1, PG-2 and pull-down transistors PD-1, PD-2, saturation current Isat of pass-gate transistors PG-1, PG-2 may be decreased. Thus, “alpha ratio” of the saturation currents, which is the ratio of saturation current Isat of pull-up transistors to saturation current Isat of pass-gate transistors, may be increased to get an enlarged write window and thus a better write margin.

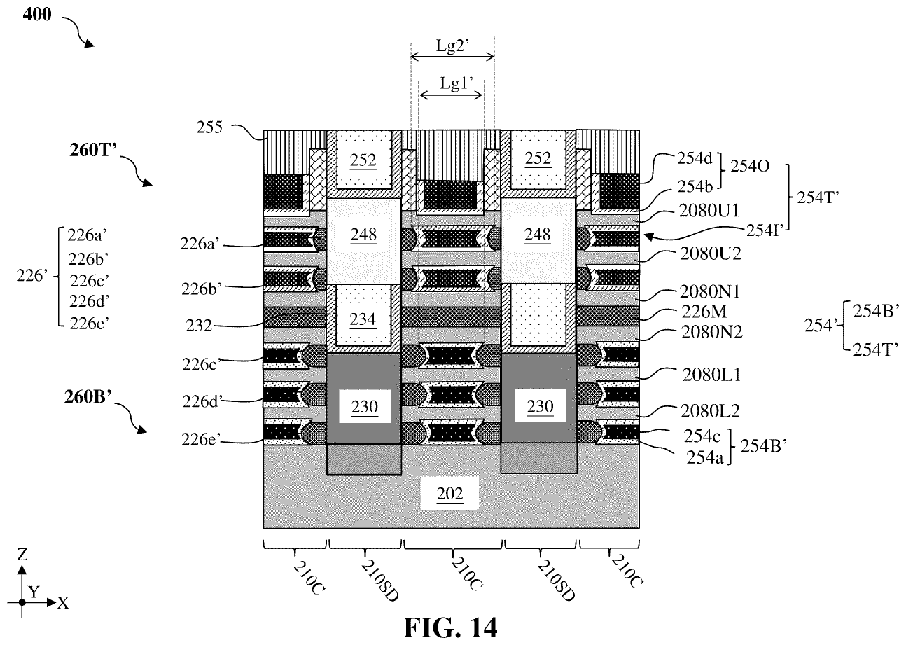

In the above embodiments described with reference to FIGS. 3-13, the first sacrificial layers 206L of the superlattice structure 204 have a germanium content less than that of the second sacrificial layers 206U, and the resulted semiconductor device 200 and the IC structure 300 include a C-FET having a top multi-gate device and a bottom multi-gate device, where a gate length Lg1 of the gate structure of the bottom multi-gate device is greater than a gate length Lg2 of the gate structure of the top multi-gate device. The top multi-gate device may be an n-type device or a p-type device, and the bottom multi-gate device may be a p-type device or an n-type device. In another alternative embodiment represented by FIG. 14, the first sacrificial layers 206L of the superlattice structure 204 have a germanium content greater than that of the second sacrificial layers 206U, and the resulted semiconductor device 400 includes a C-FET having a top multi-gate device 260T′ and a bottom multi-gate device 260B′, where a gate length Lg1′ of a gate structure 254B′ of the bottom multi-gate device 260B′ is less than a gate length Lg2′ of an inner portion 254I′ of a gate structure 254T′ of the top multi-gate device 260T′. A ratio of the gate length Lg2′ to the gate length Lg1′ is greater than 1 and less than 3. If the ratio is greater than 0.3, then the bottom gate structure may be too short, leading to weak gate control and increased leakage current. The top multi-gate device 260T′ may be an n-type device or a p-type device, and the bottom multi-gate device 260B′ may be a p-type device or an n-type device. In an embodiment, the semiconductor device 400 includes an n-type top multi-gate device 260T′ and a p-type bottom multi-gate device 260B′. Compared to existing C-FETs having a same gate length for the bottom multi-gate device and top multi-gate device, the n-type top multi-gate device 260T′ with an increased gate length Lg2′ may consume less power than the n-type top multi-gate device of the existing C-FETs. The semiconductor device 400 also includes inner spacer features 226′, and the inner spacer features 226a′-226b′ formed over the middle dielectric layer 226M have a width W2 less than a width W1 of the inner spacer features 226c′, 226d′, 226e′ formed under the middle dielectric layer 226M. Other features of the semiconductor device 400 that are similar to the semiconductor device 200 are represented by same reference numbers, and repeated description of those similar features is omitted for reason of simplicity.

In an embodiment, the semiconductor device 400 may be a portion of a logic cell (e.g., a NOR gate) that includes one or more C-FETs. A path is defined as a route to distribute signal in a circuit. A critical path is the place that mainly dominates the circuit speed (or signal distribution speed) that is dependent on different circuit applications. If the circuit speed is varied with transistors' performance significantly, then the path will be referred to as critical path; if the circuit speed is not substantially associated with transistors' performance, then the path will be referred to as a non-critical path. It is beneficial to make the critical path and the non-critical path have different configurations during field operations to reduce power consumption while maintaining satisfactory circuit speed. In an embodiment, to achieve a lower power consumption, n-type transistors in a non-critical path may be configured to similar to the top multi-gate device 260T′ of the semiconductor device 400, and p-type transistors in a critical path may be configured to similar to the bottom multi-gate device 260B′ of the semiconductor device 400. Other suitable applications are also possible.

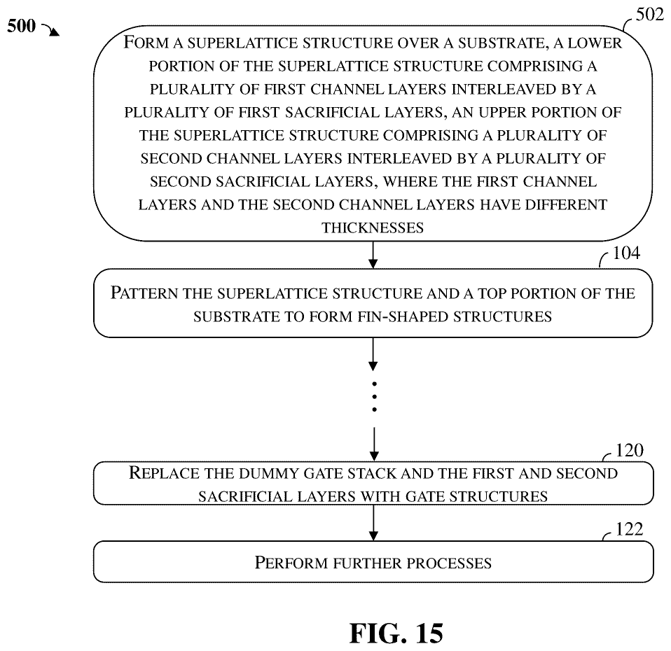

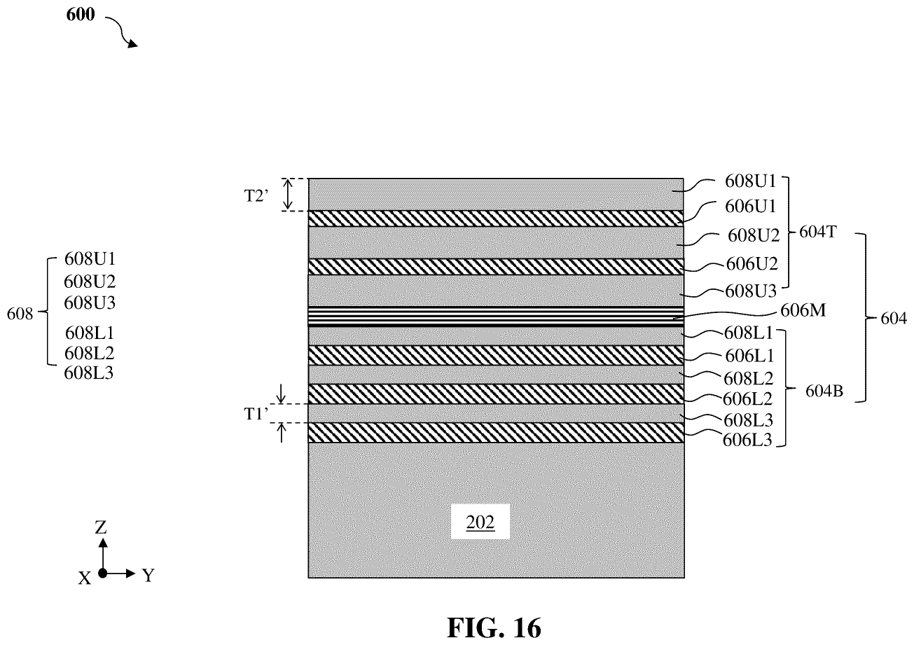

In the above embodiments, the performances of the C-FETs are optimized by individually optimizing the gate lengths of the top and bottom multi-gate devices. In another embodiment, the performances of the C-FETs may be optimized by individually optimizing channel thicknesses of the top and bottom multi-gate devices. FIG. 15 illustrates a flow chart of a method 500 for forming a semiconductor device 600 including a vertical C-FET, according to one or more aspects of the present disclosure. Method 500 is described in conjunction with FIGS. 16-20, which are fragmentary cross-sectional views of semiconductor device 600 at different stages of fabrication according to embodiments of method 500.

Referring now to FIGS. 15 and 16, method 500 includes a block 502 where a superlattice structure 604 is formed over the substrate 202. Fabrication processes for forming the superlattice structure 604 are the same as those of the superlattice structure 204. The differences between the superlattice structure 604 and the superlattice structure 204 include the dimensional relationships between different layers within the superlattice structure 604. More specifically, the superlattice structure 604 includes a bottom portion 604B, a middle sacrificial layer 606M on the bottom portion 604B, and a top portion 604T on the middle sacrificial layer 606M. The bottom portion 604B includes a number of first channel layers (e.g., first channel layers 608L1, 608L2, 608L3) interleaved by a number of first sacrificial layers (e.g., first sacrificial layers 606L1, 606L2, 606L3). The first channel layers 608L1, 608L2, 608L3 may be individually or collectively referred to as the first channel layer(s) 608L. The first sacrificial layers 606L1, 606L2, 606L3 may be individually or collectively referred to as the first sacrificial layer(s) 606L. In some implementations, the first channel layers 608L are formed of silicon (Si) and the first sacrificial layers 606L are formed of silicon germanium (SiGe).

The top portion 604T includes a number of second channel layers (e.g., second channel layers 608U1, 608U2, 608U3) interleaved by a number of second sacrificial layers (e.g., second sacrificial layers 606U1, 606U2). The second channel layers 608U1, 608U2, 608U3 may be individually or collectively referred to as the second channel layer(s) 608U. The second sacrificial layers 606U1 and 606U2 may be individually or collectively referred to as the second sacrificial layer(s) 606U. In some implementations, the second channel layers 608U are formed of silicon (Si) and the second sacrificial layers 606U are formed of silicon germanium (SiGe). In this illustrated embodiment, the first and second sacrificial layers 606L and 606U have a same germanium content that is less than the third germanium content of the middle sacrificial layer 606M. The channel layers 608L1, 608L2, 608L3, 608U1, 608U2, 608U3 will provide nanostructures for the C-FET. In some embodiments, the second channel layers 608U1-608U2 will provide channel members for a top GAA transistor of the C-FET, and the channel layers 608L2-608L3 will provide channel members for a bottom GAA transistor in the C-FET. The term “channel member(s)” is used herein to designate any material portion for channel(s) in a transistor with nanoscale dimensions, and having an elongate shape, regardless of the cross-sectional shape of this portion. In some existing technologies for forming C-FETs, the first and second channel layers 608L1 and 608U1 have a same thickness. In this embodiment, to optimize the performance of C-FETs, the first and second channel layers 608L1 and 608U1 are configured to have different thicknesses. The middle sacrificial layer 606M may be the same as the middle portion 202M.

In this illustrated embodiment, each of the first channel layers 608L1-608L2 has a thickness T1′, each of the second channel layers 608U1-608U2 has a thickness T2′. T1′ has a range the same as the thickness T1, and the thickness T2′ is greater than the thickness T1′ and less than about 30 nm. In various embodiments, a thickness of the bottommost second channel layer 608U3 that is in direct contact with the middle sacrificial layer 606M may be equal to or less than the thickness T2′, and a thickness of the top first channel layer 608L3 that is in direct contact with the middle sacrificial layer 606M may be equal to or less than the thickness T1′. In an embodiment, the thickness of the bottommost second channel layer 608U3 is equal to the thickness of the top first channel layer 608L3. By forming the first channel layers 608L1-608L2 and the second channel layers 608U1-608U2 with different thicknesses, channel resistance Rch and short channel effect of the bottom multi-gate device and the top multi-gate device may be adjusted. Thus, performance of the bottom multi-gate device and the top multi-gate device may be individually optimized.

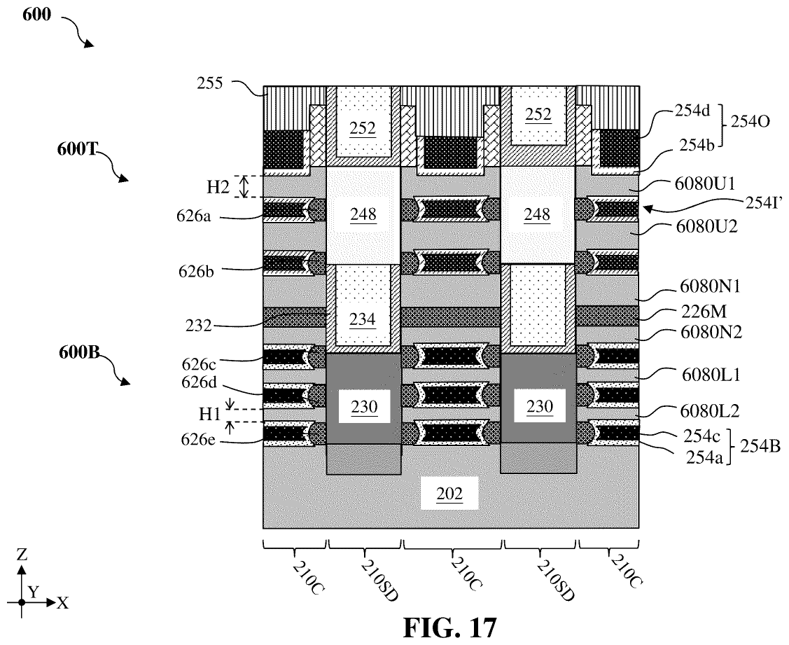

After forming the superlattice structure 604, operations in blocks 104-122 described above are performed to finish the fabrication of the semiconductor device 600. FIG. 17 depicts a fragmentary cross-section view of the semiconductor device 600 upon completion of the operations in blocks 104-122. The semiconductor device 600 is similar to the semiconductor device 200. For ease of description, similar and/or same features between two semiconductor devices 200 and 600 are represented by same references numbers, and repeated description is omitted for reason of simplicity. Main differences between the two semiconductor devices 200 and 600 are described in detail. A first one of the differences between the two semiconductor devices 200 and 600 includes that, a bottom transistor 600B of the semiconductor device 600 include channel layers 6080L1 and 6080L2 each having a sheet height H1, a top transistor 600T of the semiconductor device 600 include channel layers 6080U1 and 6080U2 each having sheet height H2, and the sheet height H1 is less than the sheet height H2. In an embodiment, a ratio between the sheet height H2 to the sheet height H1 is in a range between about 1 and about 3. If the ratio is greater than 3, then the gate control ability of the top multi-gate transistor may be too poor, leading to less precise control over drain current, or the channel layers of the bottom multi-gate transistor may be too thin, leading to a high channel resistance for the bottom multi-gate transistor. In an embodiment, the top multi-gate transistor includes an n-type multi-gate transistor, and the bottom multi-gate transistor includes a p-type multi-gate transistor, and the semiconductor device 600 may be a part of another SRAM cell of the IC structure 300 described above. That is, n-type transistors in the another SRAM cell may have thicker channel layers than p-type transistors in the another SRAM cell. In another embodiment, the top multi-gate transistor includes a p-type multi-gate transistor, and the bottom multi-gate transistor includes an n-type multi-gate transistor.

A second one of the differences between the two semiconductor devices 200 and 600 includes that, the semiconductor device 600 also includes nanostructures 6080N1 and 6080N2. The nanostructures 6080N1 and 6080N2 may have different sheet thicknesses. A third one of the differences between the two semiconductor devices 200 and 600 includes that, the semiconductor device 600 also includes inner spacer features, such as inner spacer features 626a, 626b, 626c, 626d, and 626e. Widths of the inner spacer features 626a-626e of the semiconductor device 600 may be substantially the same.

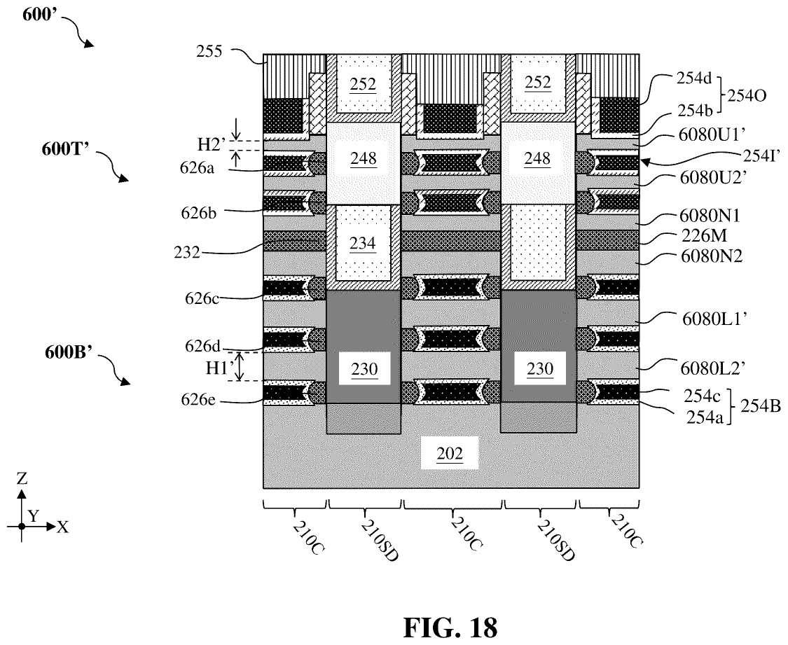

In the above embodiment described with reference to FIG. 17, the sheet height H2 of the top multi-gate transistor 600T is greater than the sheet height H1 of the bottom multi-gate transistor 600B. In another embodiment represented by FIG. 18, an alternative semiconductor device 600′ is depicted. The semiconductor device 600′ is similar to the semiconductor device 600, and one of the differences between the semiconductor device 600 and the semiconductor device 600′ includes that the top multi-gate transistor 600T′ and the bottom multi-gate transistor 600B′ have a different sheet height relationship. More specifically, the bottom multi-gate transistor 600B′ includes channel layers 6080L1′ and 6080L2′ each having a sheet height H1′, the top multi-gate transistor 600T′ includes channel layers 6080U1′ and 6080U2′ each having a sheet height H2′, and the sheet height H1′ is greater than the sheet height H2′. In an embodiment, a ratio of the sheet height H2′ to the sheet height H1′ is greater than about 0.3 and less than 1. If the ratio is less than 0.3, then the gate control ability of the bottom multi-gate transistor 600B′ may be too poor, leading to less precise control over drain current, or the channel layers of the top multi-gate transistor 600T′ may be too thin, leading to a high channel resistance for the top multi-gate transistor. In an embodiment, the top multi-gate transistor 600T′ includes an n-type multi-gate transistor, and the bottom multi-gate transistor 600B′ includes a p-type multi-gate transistor, and the semiconductor device 600′ may be in a non-critical path of another logic cell that is similar to the logic cell described above. In another embodiment, the top multi-gate transistor includes a p-type multi-gate transistor, and the bottom multi-gate transistor includes an n-type multi-gate transistor.

Four embodiments have been described above with reference to FIGS. 9, 14, 17, and 18. Key concepts (e.g., different gate lengths, different sheet heights) of those four embodiments can be combined to form four different alternative embodiments.

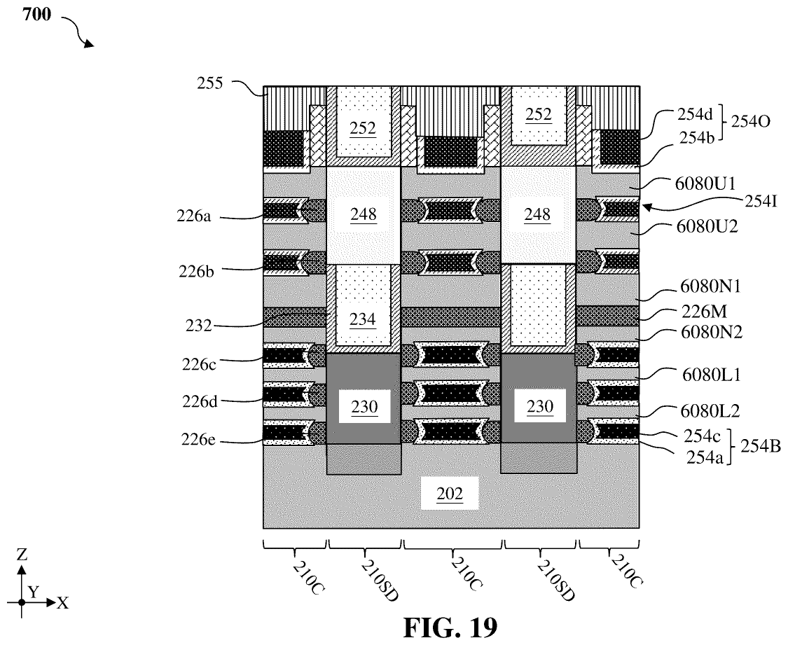

FIG. 19 depicts a first one of the four alternative embodiments. With reference to FIG. 19, a semiconductor device 700 is illustrated. In this embodiment, the semiconductor device 700 includes the inner spacer features 226, the bottom gate structure 254B and the inner portion 254I of the top gate structure, and the channel layers 6080U1-6080U2 and 6080L1-6080L2. The gate length relationship and the channel sheet height relationship have been described above with reference to FIGS. 9 and 17, and repeated description is omitted for reason of simplicity. In an embodiment, the semiconductor device 700 may be a part of another SRAM cell of the IC structure to increase the alpha ratio of this another SRAM cell.

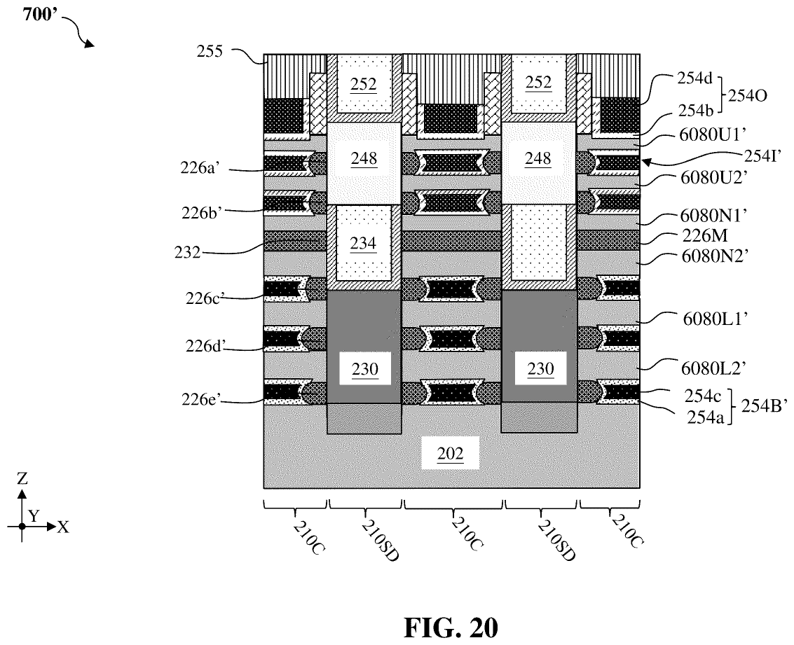

FIG. 20 depicts a second one of the four alternative embodiments. With reference to FIG. 20, a semiconductor device 700′ is illustrated. In this embodiment, the semiconductor device 700′ includes the inner spacer features 226′, the bottom gate structure 254B′ and the inner portion 254I′ of the top gate structure, and the channel layers 6080U1′-6080U2′ and 6080L1′-6080L2′. The gate length relationship and the channel sheet height relationship have been described above with reference to FIGS. 14 and 18, and repeated description is omitted for reason of simplicity. In an embodiment, the semiconductor device 700′ may be in a non-critical path of another logic cell.

Another two embodiments of the four alternative embodiments are not explicitly shown by figures. However, it is note that, a third embodiment of the four alternative embodiments may include a C-FET having the inner portion 254I and the bottom gate structure 254B, the inner spacer features 226, and also the channel layers 6080U1′-6080U2′ and 6080L1′-6080L2′. A fourth embodiment of the four alternative embodiments may include a C-FET having the inner portion 254I′ and the bottom gate structure 254B′, the inner spacer features 226′, and also the channel layers 6080U1-6080U2 and 6080L1-6080L2.

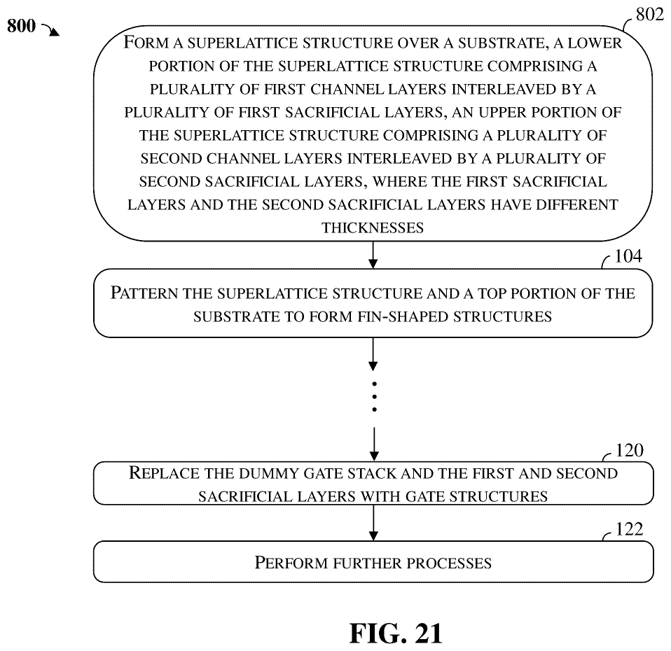

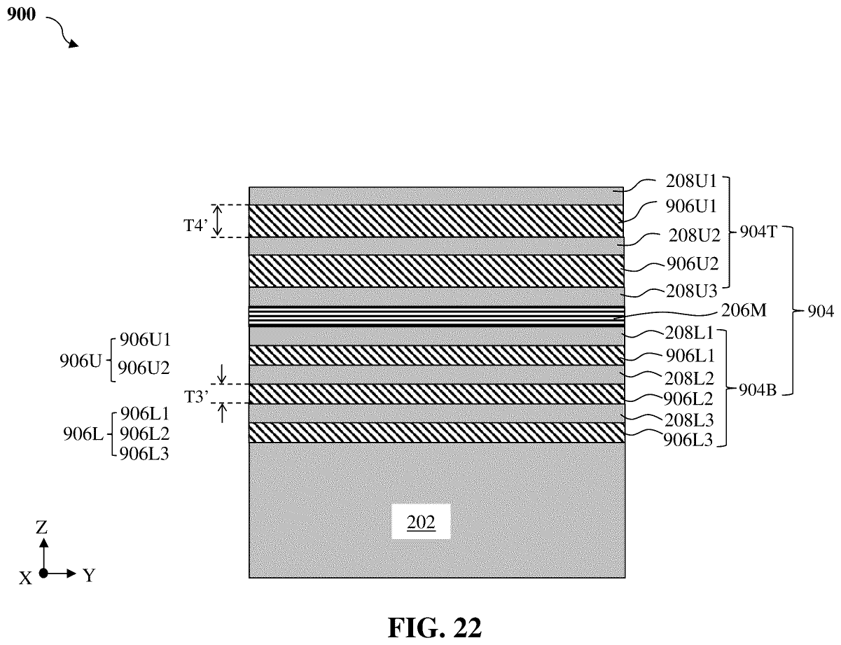

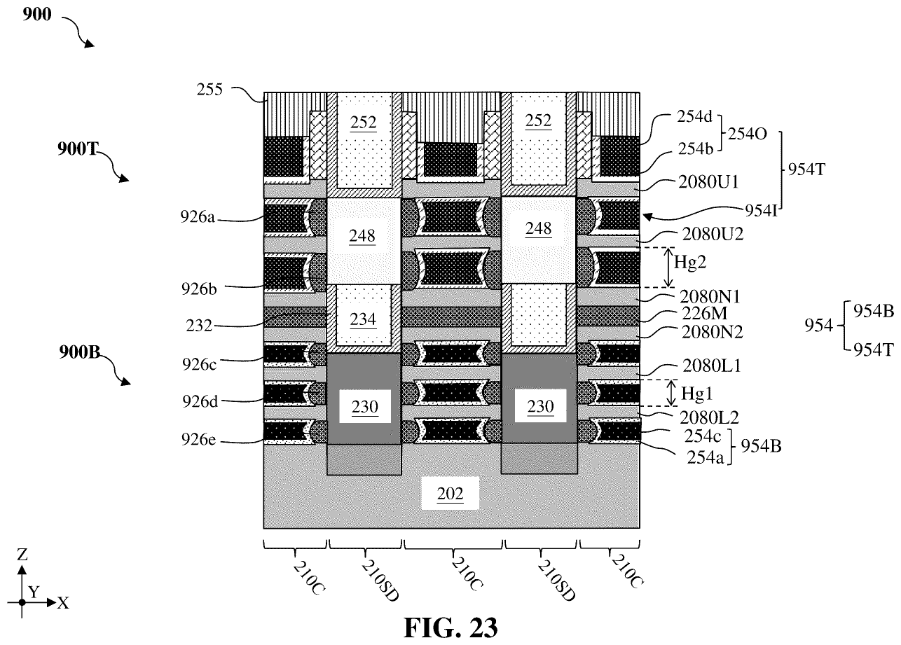

The performances of the C-FETs can also be optimized by individually optimizing the gate heights of the top and bottom multi-gate devices. FIG. 21 illustrates a flow chart of a method 800 for forming a semiconductor device 900 including a vertical C-FET, according to one or more aspects of the present disclosure. Method 800 is described in conjunction with FIGS. 22-23, which are fragmentary cross-sectional views of semiconductor device 900 at different stages of fabrication according to embodiments of method 800.

Referring now to FIGS. 21 and 22, method 800 includes a block 802 where a superlattice structure 904 is formed over the substrate 202. Fabrication processes for forming the superlattice structure 904 are the same as those of the superlattice structure 204. The differences between the superlattice structure 904 and the superlattice structure 204 include the dimensional relationships between different layers within the superlattice structure 904. More specifically, the superlattice structure 904 includes a bottom portion 904B, the middle sacrificial layer 206M on the bottom portion 904B, and a top portion 904T on the middle sacrificial layer 206M. The bottom portion 904B includes a number of first channel layers (e.g., the first channel layers 208L1, 208L2, 208L3) interleaved by a number of first sacrificial layers (e.g., first sacrificial layers 906L1, 906L2, 906L3). The first sacrificial layers 906L1, 906L2, 906L3 may be individually or collectively referred to as the first sacrificial layer(s) 906L. In some implementations, the first channel layers 208L are formed of silicon (Si) and the first sacrificial layers 906L are formed of silicon germanium (SiGe). The top portion 904T includes a number of second channel layers (e.g., second channel layers 208U1, 208U2, 208U3) interleaved by a number of second sacrificial layers (e.g., second sacrificial layers 906U1, 906U2). The second sacrificial layers 906U1 and 906U2 may be individually or collectively referred to as the second sacrificial layer(s) 906U. In some implementations, the second channel layers 208U are formed of silicon (Si) and the second sacrificial layers 906U are formed of silicon germanium (SiGe). The first channel layers 208L and the second channel layers 208U may have a same thickness. In this illustrated embodiment, the first and second sacrificial layers 906L and 906U have a same germanium content that is less than the third germanium content of the middle sacrificial layer 206M.

In some existing technologies for forming C-FETs, the first and second sacrificial layers 906L and 906U have a same thickness, and as a result, heights the bottom gate structure and the inner portion of the top gate structure may be the same. In this embodiment, to optimize the performance of C-FETs, the first and second sacrificial layers 906L and 906U are configured to have different thicknesses. In this illustrated embodiment, each of the first sacrificial layers 906L has a thickness T3′, each of the second sacrificial layers 906U has a thickness T4′. T3′ has a range the same as the thickness T3, and the thickness T4′ is greater than the thickness T4′ and less than about 30 nm. By forming the first sacrificial layers 906L and the second sacrificial layers 906U with different thicknesses, spacing for forming gate structures therein may be adjusted. Thus, thicknesses and/or number of different layers of the gate structures of the bottom multi-gate device and the top multi-gate device may be individually optimized.

After forming the superlattice structure 904, operations in blocks 104-122 described above are performed to finish the fabrication of the semiconductor device 900. FIG. 23 depicts a fragmentary cross-section view of the semiconductor device 900 upon completion of the operations in blocks 104-122. The semiconductor device 900 is similar to the semiconductor device 200. For ease of description, similar and/or same features between two semiconductor devices 200 and 900 are represented by same references numbers, and repeated description is omitted for reason of simplicity. Main differences between the two semiconductor devices 200 and 900 are described in detail. A first one of the differences between the two semiconductor devices 200 and 900 includes that, a bottom multi-gate transistor 900B of the semiconductor device 900 includes a gate structure 954B having a first gate height Hg1, an inner portion 954I of a top gate structure 954T of a top multi-gate transistor 900T includes a second gate height Hg2. The second gate height Hg2 is greater than the first gate height Hg1. In an embodiment, the top multi-gate transistor 900T includes an n-type multi-gate transistor, and the bottom multi-gate transistor 900B includes a p-type multi-gate transistor. In another embodiment, the top multi-gate transistor 900T includes a p-type multi-gate transistor, and the bottom multi-gate transistor 900B includes an n-type multi-gate transistor. A second one of the differences between the two semiconductor devices 200 and 900 includes that, the semiconductor device 900 also includes inner spacer features, such as inner spacer features 926a, 926b, 926c, 926d, and 926e. Widths of the inner spacer features 926a-926e of the semiconductor device 900 may be substantially the same. However, the inner spacer features 926a-926e may have different heights. In this embodiment, a height of the inner spacer features 926a-926b formed over the middle dielectric layer 226M is greater than a height of the inner spacer features 926c-926e formed below the middle dielectric layer 226M.

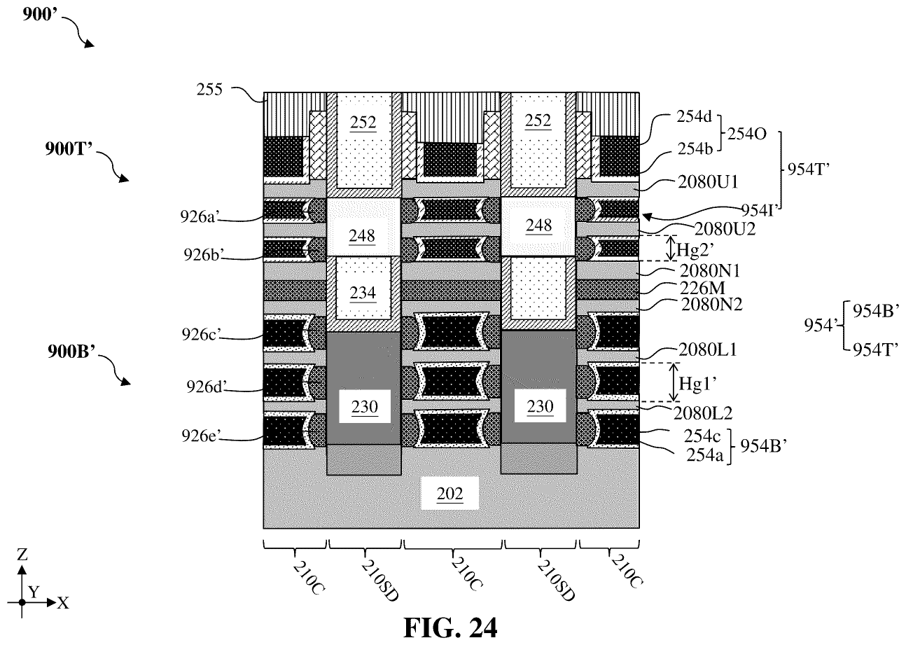

In the above embodiment described with reference to FIG. 23, the gate height Hg2 of the top multi-gate transistor 900T is greater than the gate height Hg1 of the bottom multi-gate transistor 900B. In another embodiment represented by FIG. 24, an alternative semiconductor device 900′ is depicted. The semiconductor device 900′ is similar to the semiconductor device 900, and one of the differences between the semiconductor device 900 and the semiconductor device 900′ includes that the top multi-gate transistor 900T′ and the bottom multi-gate transistor 900B′ have a different gate height relationship. More specifically, the bottom multi-gate transistor 900B′ includes a bottom gate structure having a gate height Hg1′, the top multi-gate transistor 900T′ includes a top gate structure 954T′ including an inner portion 954I′ having a gate height Hg2′, and the height Hg1′ is greater than the height Hg2′. In this embodiment, the semiconductor device 900′ also includes inner spacer features 926a′, 926b′, 926c′, 926d′, and 926e′. Widths of the inner spacer features 926a′-926e′ of the semiconductor device 900′ may be substantially the same. However, the inner spacer features 926a′-926e′ may have different heights. In this embodiment, a height of the inner spacer features 926a′-926b′ formed over the middle dielectric layer 226M is less than a height of the inner spacer features 926c′-926e′ formed below the middle dielectric layer 226M.

Six main embodiments have been described above with reference to FIGS. 9, 14, 17, 18, 23, and 24. Two or three of the key concepts (e.g., different gate lengths, different sheet heights, different gate heights) of those six embodiments can be combined to form different alternative embodiments to flexibly adjust the performance of the C-FETs.

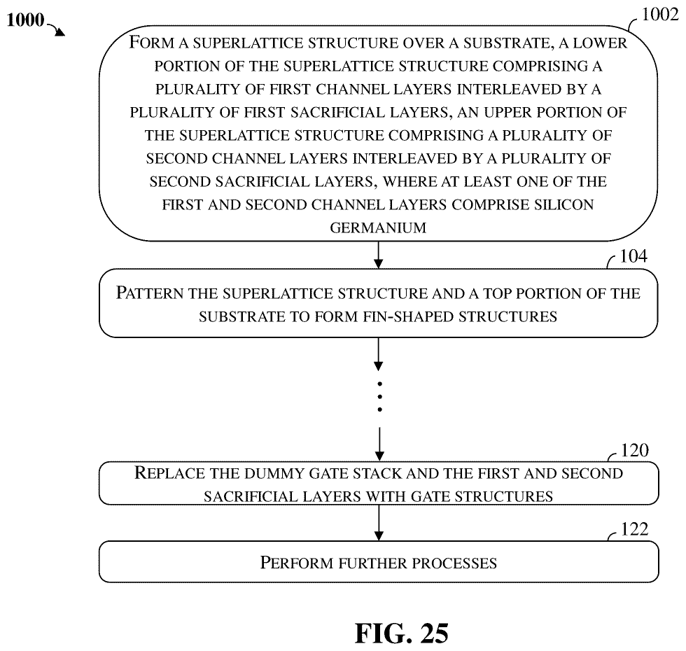

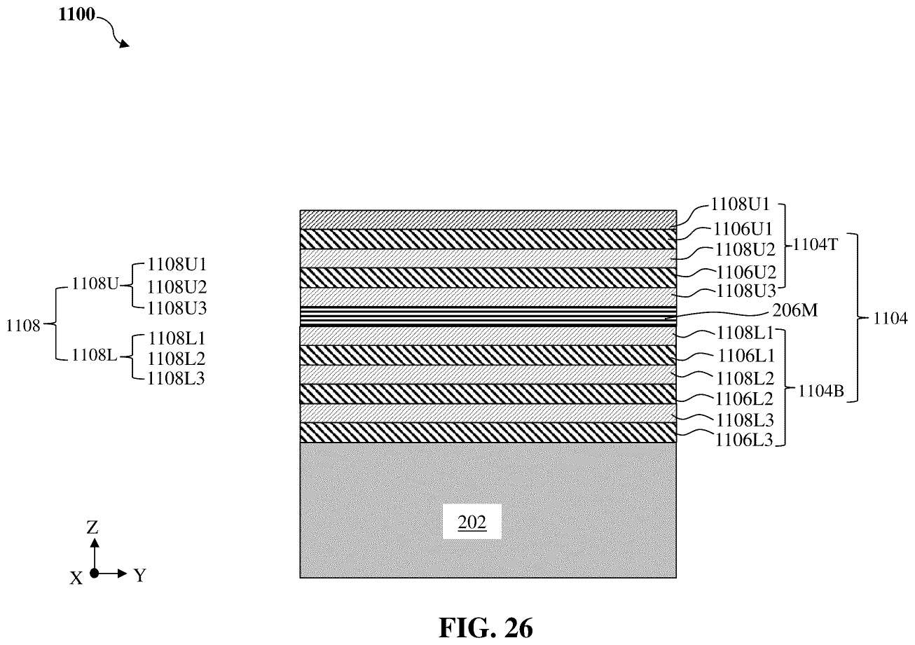

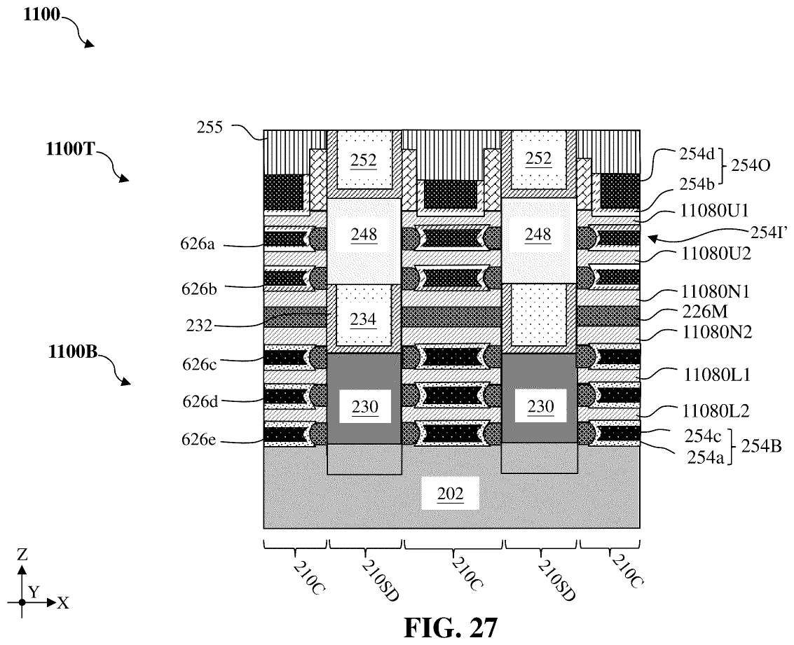

The performances of the C-FETs can also be optimized by individually optimizing compositions of channel layers of the top and bottom multi-gate devices. FIG. 25 illustrates a flow chart of a method 1000 for forming a semiconductor device 1100 including a vertical C-FET, according to one or more aspects of the present disclosure. Method 1000 is described in conjunction with FIGS. 26-27, which are fragmentary cross-sectional views of semiconductor device 1100 at different stages of fabrication according to embodiments of method 1000.

Referring now to FIGS. 25 and 26, method 1000 includes a block 1002 where a superlattice structure 1104 is formed over the substrate 202. Fabrication processes for forming the superlattice structure 1104 are the same as those of the superlattice structure 204. The differences between the superlattice structure 1104 and the superlattice structure 204 include that the superlattice structures 204 and 904 have different compositions. More specifically, the superlattice structure 1104 includes a bottom portion 1104B, the middle sacrificial layer 206M on the bottom portion 1104B, and a top portion 1104T on the middle sacrificial layer 206M. The bottom portion 1104B includes a number of first channel layers (e.g., the first channel layers 1108L1, 1108L2, 1108L3) interleaved by a number of first sacrificial layers (e.g., first sacrificial layers 1106L1, 1106L2, 1106L3). The first sacrificial layers 1106L1, 1106L2, 1106L3 may be individually or collectively referred to as the first sacrificial layer(s) 1106L. The top portion 1104T includes a number of second channel layers (e.g., second channel layers 1108U1, 1108U2, 1108U3) interleaved by a number of second sacrificial layers (e.g., second sacrificial layers 1106U1, 1106U2). The second sacrificial layers 1106U1, 1106U2 may be individually or collectively referred to as the second sacrificial layer(s) 1106U.

In some existing technologies for forming C-FETs, the first and second channel layers in the bottom portion and the top portion are both formed of silicon. In this embodiment, to optimize the performance of C-FETs, the first channel layers 1108L and/or the second channel layers 1108U are formed of silicon germanium. In this illustrated embodiment, both the first channel layers 1108L and the second channel layers 1108U includes silicon germanium having a same first germanium content, and both the first sacrificial layers 1106L and the second sacrificial layers 1106U includes silicon germanium having a same second germanium content that is greater than the first germanium content of the first channel layers 1108L and/or the second channel layers 1108U and less than a germanium content of the middle sacrificial layer 206M. In an embodiment, the first germanium content is less than 30%, the second germanium content is between about 40% and about 50%, and the germanium content of the middle sacrificial layer 206M is between about 60% and about 100%. The higher second germanium content and the highest germanium content of the middle sacrificial layer 206M provide etch selectivity among the three SiGe-based channel layers and sacrificial layers of the superlattice structure 1104.

After forming the superlattice structure 1104, operations in blocks 104-122 described above are performed to finish the fabrication of the semiconductor device 1100. FIG. 27 depicts a fragmentary cross-section view of the semiconductor device 1100 upon completion of the operations in blocks 104-122. The semiconductor device 1100 is similar to the semiconductor device 200 and the semiconductor device 600. For ease of description, similar and/or same features between the semiconductor devices 200, 600 and 1100 are represented by same references numbers, and repeated description is omitted for reason of simplicity. Main differences between the two semiconductor devices 200, 600 and 1100 are described in detail. A first one of the differences between the two semiconductor devices 200 and 1100 includes that, a bottom multi-gate transistor 1100B of the semiconductor device 1100 includes channel members 11080L1 and 11080L2 formed from the channel layers 1108L2 and 1108L3, and a top multi-gate transistor 1100T of the semiconductor device 1100 includes channel members 11080U1 and 11080U2 formed from the channel layers 1108U1 and 1108U3, where the channel members 11080U1-11080U2 and 11080L1-11080L2 are formed of silicon germanium having the germanium content less than 30%. The semiconductor device 1100 also includes nanostructures 11080N1 and 11080N2 formed from the channel layers 1108U3 and 1108L1 and includes silicon germanium having the germanium content less than 30%. Another difference between the two semiconductor devices 200 and 1100 includes that the bottom multi-gate transistor 1100B includes inner spacer features 626c-626e, and the top multi-gate transistor 1100T includes inner spacer features 626a-626b. The inner spacer features 626a-626e have a same width. In an embodiment, the top multi-gate transistor 1100T includes an n-type multi-gate transistor, and the bottom multi-gate transistor 1100B includes a p-type multi-gate transistor. In another embodiment, the top multi-gate transistor 1100T includes a p-type multi-gate transistor, and the bottom multi-gate transistor 1100B includes an n-type multi-gate transistor.

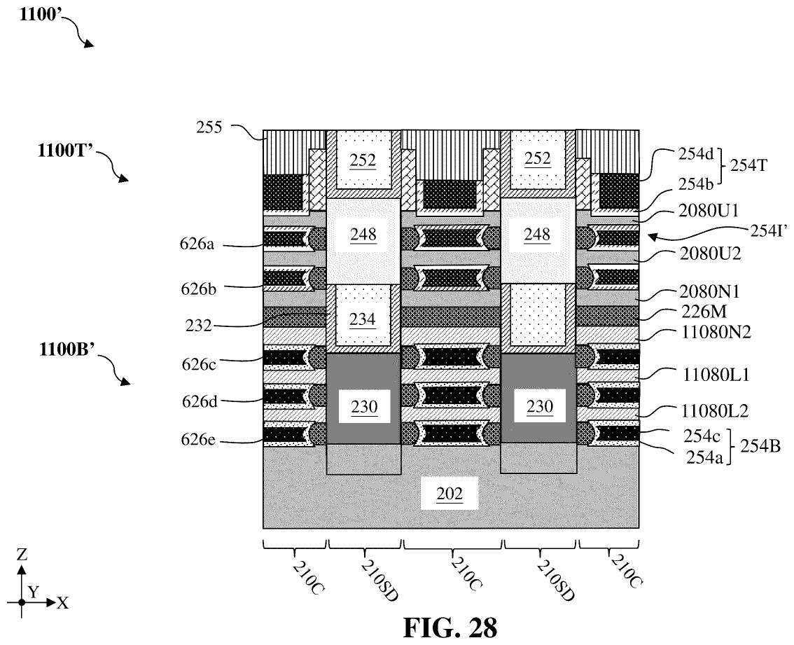

In the above embodiment described with reference to FIG. 27, both the first channel layers 1108L and the second channel layers 1108U includes silicon germanium having the same first germanium content. In another embodiment represented by FIG. 28, an alternative semiconductor device 1100′ is depicted. The semiconductor device 1100′ is similar to the semiconductor device 1100, and one of the differences between the semiconductor device 1100 and the semiconductor device 1100′ includes that the first channel layers of the bottom multi-gate transistor 1100B′ and the second channel layers of the top multi-gate transistor 1100T′ have different compositions. More specifically, in this illustrated embodiment, the bottom multi-gate transistor 1100B′ includes the channel members 11080L1-11080L2 formed of silicon germanium, and the top multi-gate transistor 1100T′ includes channel members 2080U1 and 2080U2 formed of silicon. The semiconductor device 1100′ also includes nanostructures 2080N1 and 11080N2. In an embodiment, the top multi-gate transistor 1100T′ includes an n-type multi-gate transistor, and the bottom multi-gate transistor 1100B′ includes a p-type multi-gate transistor. In another embodiment, the top multi-gate transistor 1100T′ includes a p-type multi-gate transistor, and the bottom multi-gate transistor 1100B′ includes an n-type multi-gate transistor. Although not shown, the method 1000 may also be applied to fabricate a semiconductor device including a top multi-gate transistor having channel members formed of silicon germanium and a bottom multi-gate transistor having channel members formed of silicon.

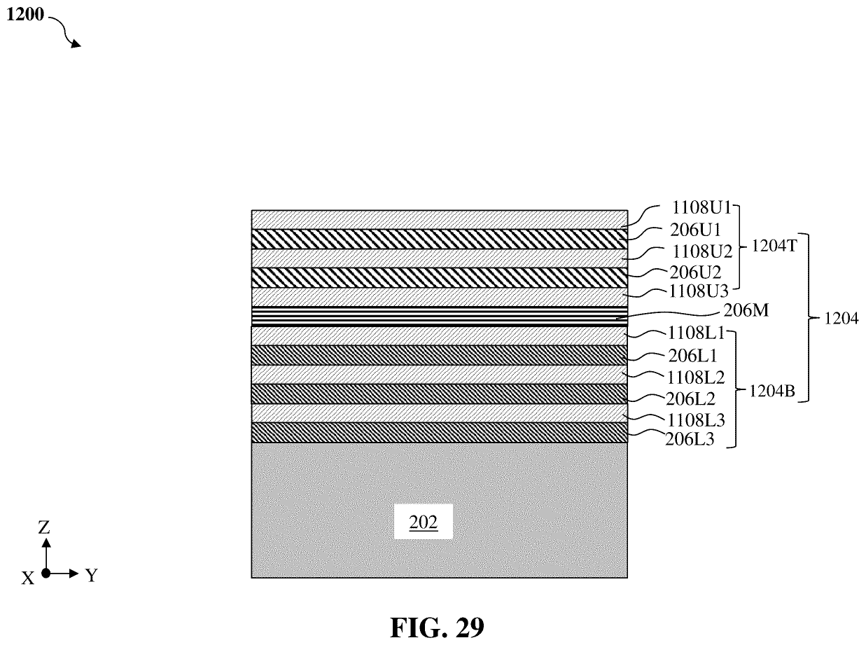

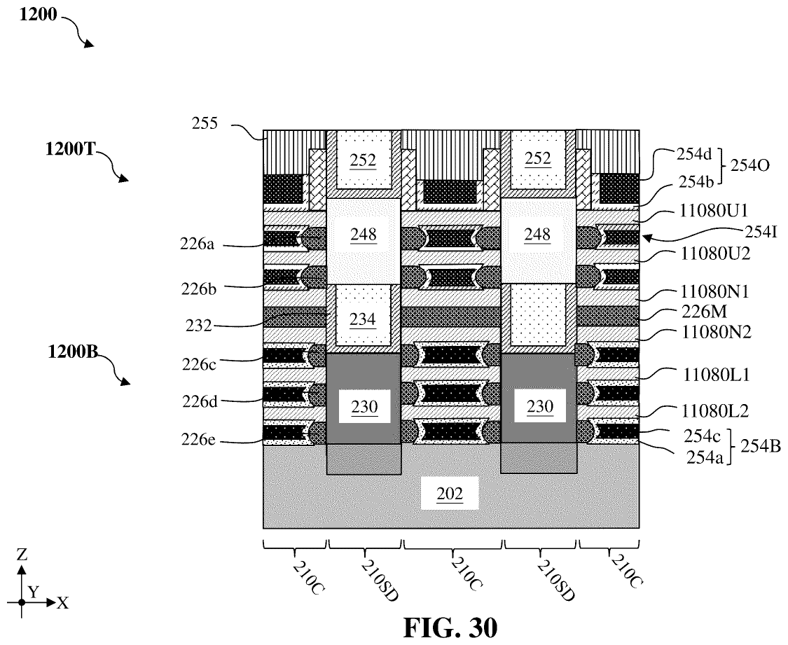

The concept of method 1000 can also be combined with other embodiments described above with reference to FIGS. 9, 14, 17, 18, 23, and 24. For example, FIGS. 29-30 depict fragmentary cross-sectional views of a semiconductor device 1200 during various fabrication processes. The semiconductor device 1200 is similar to the semiconductor device 200 and the semiconductor device 1100. For ease of description, similar and/or same features between the semiconductor devices 200, 1100 and 1200 are represented by same references numbers, and repeated description is omitted for reason of simplicity. Main differences between the semiconductor devices 200, 1100 and 1200 are described in detail. More specifically, FIG. 29 depicts a superlattice structure 1204 formed over the substrate 202. The superlattice structure 1204 includes the channel layers 1108 interleaved by the sacrificial layers 206. That is, first channel layers 1108L and second channel layers 1108U include silicon germanium having the same first germanium content. The superlattice structure 1204 also includes the sacrificial layers 206 described above with reference to FIG. 3. That is, the first sacrificial layers 206L and the second sacrificial layers 206U have different germanium contents. It is noted, both germanium contents of the first sacrificial layers 206L and the second sacrificial layers 206U are greater than the germanium content of the channel layers 1108.

After forming the superlattice structure 1204, operations in blocks 104-122 described above are performed to finish the fabrication of the semiconductor device 1200 represented by FIG. 30. Differences between the semiconductor devices 200, 1100 and 1200 include that, the semiconductor device 1200 includes the channel members 11080U1-11080U2 and 11080L1 and 11080L2 described with reference to FIG. 27 and also includes the gate structures 254B and 254I and inner spacer features 226 described with reference to FIG. 9. That is, channel members of the semiconductor device 1200 may include silicon germanium, and gate lengths of a gate structure of a bottom multi-gate transistor 1200B of the semiconductor device 1200 and an inner portion of a gate structure of a top multi-gate transistor 1200T of the semiconductor device 1200 are different.

In the above embodiment described with reference to FIG. 30, channel members of the bottom multi-gate transistor 1200B and channel members of the top multi-gate transistor 1200T both include silicon germanium.

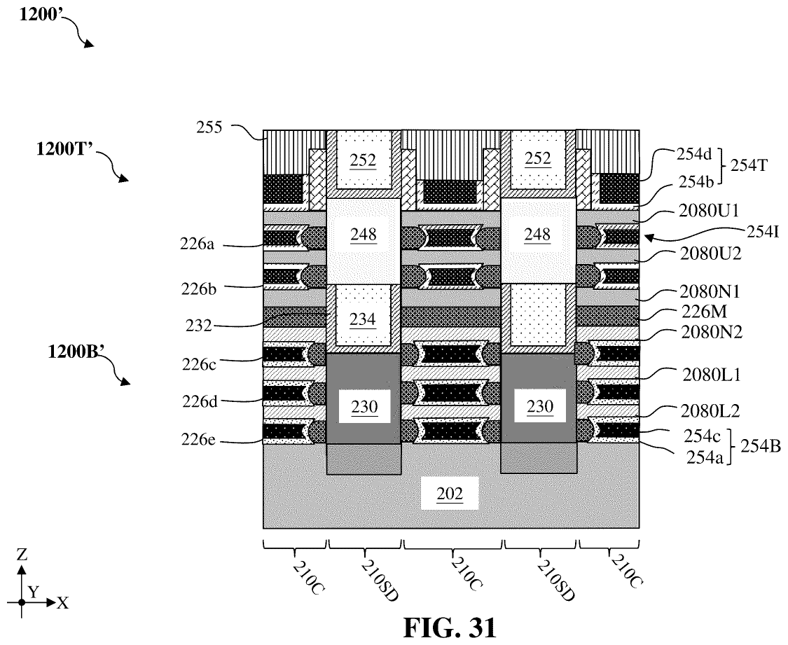

In another embodiment represented by FIG. 31, an alternative semiconductor device 1200′ is depicted. The semiconductor device 1200′ is similar to the semiconductor device 1200, and one of the differences between the semiconductor device 1200 and the semiconductor device 1200′ includes that, channel members of a bottom multi-gate transistor 1200B′ of the semiconductor device 1200′ and channel members of a top multi-gate transistor 1200T′ of the semiconductor device 1200′ are different. In this illustrated embodiment, the bottom multi-gate transistor 1200B′ includes channel members 2080U1 and 2080U2 formed of silicon, and the top multi-gate transistor 1200T′ includes channel members 11080L1 and 11080L2 formed of silicon germanium.

The present disclosure includes optimizing different aspects (e.g., gate lengths, channel sheet thicknesses, gate heights, channel member compositions) of the bottom multi-gate transistor and the top multi-gate transistor of C-FETs to achieve different performance boost. Those different aspects may be applied individually or can be combined in various ways to form different C-FETs. Although only some of those combinations are explicitly shown or described, it is understood that the present disclosure encompasses all those combinations.

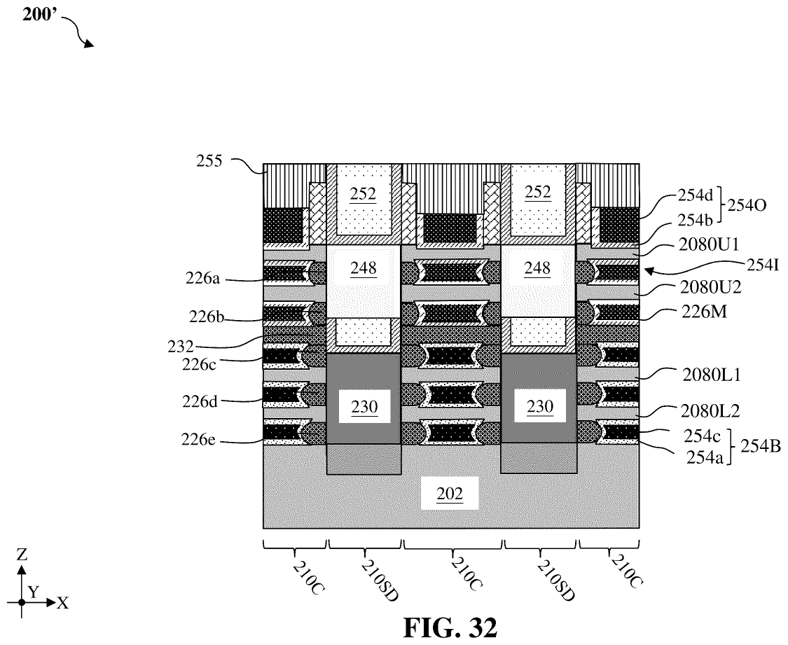

In the embodiments described above with reference to FIGS. 2-31, the semiconductor devices all include the nanostructures (e.g., 2080N1 and 2080N2 shown in FIG. 9) in direct contact with the middle dielectric layer 226M. In some alternative embodiments, as represented by FIG. 32, such nanostructures may be omitted. FIG. 32 depicts a fragmentary cross-sectional view of an alternative semiconductor device 200′. The semiconductor device 200′ is similar to the semiconductor device 200, and one of the differences between the semiconductor devices 200 and 200′ includes that, the semiconductor device 200′ does not include the 2080N1 and 2080N2. That is, the middle dielectric layer 226M is in direct contact with the top gate structure 254T and the bottom gate structure 254B. This alternative embodiment can be applied to any one of the embodiments described above with reference to FIGS. 13-31 as well.

Although not intended to be limiting, one or more embodiments of the present disclosure provide many benefits to a semiconductor device and the formation thereof. For example, the present disclosure provides a C-FET device having a top multi-gate device and a bottom multi-gate device. One or more of features of the top multi-gate device and a bottom multi-gate device can be optimized to boost the performance of the C-FET device. Such feature may include gate lengths, gate heights, channel sheet thickness, and/or channel member compositions.

The present disclosure provides for many different embodiments. Semiconductor structures and methods of fabrication thereof are disclosed herein. In one exemplary aspect, the present disclosure is directed to a method. The method includes forming a fin-shaped structure protruding from a substrate, a first portion of the fin-shaped structure comprising a plurality of first channel layers interleaved by a plurality of first sacrificial layers, and a second portion of the fin-shaped structure comprising a plurality of second channel layers interleaved by a plurality of second sacrificial layers, forming a trench extending through the fin-shaped structure, after the forming of the trench, performing an etching process to laterally recess the plurality of first sacrificial layers and the plurality of second sacrificial layers, wherein an etchant of the etching process etches the plurality of first sacrificial layers and the plurality of second sacrificial layers at different rates, and after the performing of the etching process, replacing a remaining portion of the plurality of first sacrificial layers with a first gate structure and replacing a remaining portion of the plurality of second sacrificial layers with a second gate structure.

In some embodiments, the plurality of first sacrificial layers may include silicon germanium having a first germanium concentration, the plurality of second sacrificial layers may include silicon germanium having a second germanium concentration greater than the first germanium concentration. In some embodiments, a length of the first gate structure is greater than a length of the second gate structure. In some embodiments, the method may also include, before the replacing, forming a first source/drain feature coupled to the plurality of first channel layers, and forming a second source/drain feature coupled to the plurality of second channel layers, the first source/drain feature and the second source/drain feature are of different conductivity types. In some embodiments, the method may also include, after the performing of the etching process, forming first inner spacer features adjoining the remaining portion of the plurality of first sacrificial layers, and forming second inner spacer features adjoining the remaining portion of the plurality of second sacrificial layers. In some embodiments, the first inner spacer features and the second inner spacer features have different widths. In some embodiments, the fin-shaped structure may also include a middle portion disposed vertically between the first portion and the second portion, and the method may also include selectively removing the middle portion to form an opening and forming a dielectric layer in the opening. In some embodiments, the middle portion may include silicon germanium, and a germanium concentration of the middle portion is greater than a germanium concentration the plurality of first sacrificial layers and a germanium concentration of the plurality of second sacrificial layers. In some embodiments, each of the plurality of first channel layers has a first thickness, each of the plurality of second channel layers has a second thickness different than the first thickness.

In another exemplary aspect, the present disclosure is directed to a method. The method includes forming a first semiconductor layer stack over a substrate and a second semiconductor layer stack over the first semiconductor layer stack, the first semiconductor layer stack having a first upper semiconductor layer over a first lower semiconductor layer, and the second semiconductor layer stack having a second upper semiconductor layer over a second lower semiconductor layer, forming a first source/drain feature coupled to the first upper semiconductor layer and the first lower semiconductor layer, forming a second source/drain feature coupled to the second upper semiconductor layer and the second lower semiconductor layer, forming a first gate structure disposed adjacent to the first source/drain feature and between the first upper semiconductor layer and the first lower semiconductor layer, and forming a second gate structure disposed adjacent to the second source/drain feature and between the second upper semiconductor layer and the second lower semiconductor layer, the first gate structure and the second gate structure have different gate lengths.

In some embodiments, the first semiconductor layer stack and the second semiconductor layer stack have a same width. In some embodiments, the first source/drain feature may include p-type dopants, the second source/drain feature may include n-type dopants, and a gate length of the first gate structure is greater than a gate length of the second gate structure. In some embodiments, a thickness of the first lower semiconductor layer is less than a thickness of the second upper semiconductor layer. In some embodiments, the method may also include forming a first inner spacer disposed between the first gate structure and the first source/drain feature, and forming a second inner spacer disposed between the second gate structure and the second source/drain feature. In some embodiments, the first inner spacer and the second inner spacer have different widths. In some embodiments, the method may also include forming a dielectric layer between the first semiconductor layer stack and the second semiconductor layer stack, where the dielectric layer, the first inner spacer, and the second inner spacer have a same composition.

In yet another exemplary aspect, the present disclosure is directed to a semiconductor device. The semiconductor device includes a substrate, a lower source/drain feature disposed over the substrate, a first plurality of nanostructures coupled to the lower source/drain feature, a first gate structure wrapping around each of the first plurality of nanostructures, an upper source/drain feature over the lower source/drain feature, a second plurality of nanostructures coupled to the upper source/drain feature, and a second gate structure wrapping around each of the second plurality of nanostructures, where the first gate structure and the second gate structure have different gate lengths.

In some embodiments, the lower source/drain feature may include p-type dopants, the upper source/drain feature may include n-type dopants, and a gate length of the first gate structure is greater than a gate length of the second gate structure. In some embodiments, the semiconductor device may also include a first inner spacer disposed between the first gate structure and the lower source/drain feature, and a second inner spacer disposed between the second gate structure and the upper source/drain feature, the first inner spacer and the second inner spacer have different widths. In some embodiments, a thickness of each of the first plurality of nanostructures is different than a thickness of each of the second plurality of nanostructures.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure protruding from a substrate, a first portion of the fin-shaped structure comprising a plurality of first channel layers interleaved by a plurality of first sacrificial layers, and a second portion of the fin-shaped structure comprising a plurality of second channel layers interleaved by a plurality of second sacrificial layers;
forming a trench extending through the fin-shaped structure;
after the forming of the trench, performing an etching process to laterally recess the plurality of first sacrificial layers and the plurality of second sacrificial layers, wherein an etchant of the etching process etches the plurality of first sacrificial layers and the plurality of second sacrificial layers at different rates; and
after the performing of the etching process, replacing a remaining portion of the plurality of first sacrificial layers with a first gate structure and replacing a remaining portion of the plurality of second sacrificial layers with a second gate structure.

2. The method of claim 1, wherein the plurality of first sacrificial layers comprise silicon germanium having a first germanium concentration, the plurality of second sacrificial layers comprise silicon germanium having a second germanium concentration greater than the first germanium concentration.

3. The method of claim 2, wherein a length of the first gate structure is greater than a length of the second gate structure.

4. The method of claim 1, further comprising:
before the replacing, forming a first source/drain feature coupled to the plurality of first channel layers; and
forming a second source/drain feature coupled to the plurality of second channel layers, wherein the first source/drain feature and the second source/drain feature are of different conductivity types.

5. The method of claim 1, further comprising:
after the performing of the etching process, forming first inner spacer features adjoining the remaining portion of the plurality of first sacrificial layers; and
forming second inner spacer features adjoining the remaining portion of the plurality of second sacrificial layers.

6. The method of claim 5, wherein the first inner spacer features and the second inner spacer features have different widths.

7. The method of claim 1, wherein the fin-shaped structure further comprises a middle portion disposed vertically between the first portion and the second portion, and the method further comprises:
selectively removing the middle portion to form an opening; and
forming a dielectric layer in the opening.

8. The method of claim 7, wherein the middle portion comprises silicon germanium, and a germanium concentration of the middle portion is greater than a germanium concentration the plurality of first sacrificial layers and a germanium concentration of the plurality of second sacrificial layers.

9. The method of claim 1, wherein each of the plurality of first channel layers has a first thickness, each of the plurality of second channel layers has a second thickness different than the first thickness.

10. A method, comprising:
forming a first semiconductor layer stack over a substrate and a second semiconductor layer stack over the first semiconductor layer stack, the first semiconductor layer stack having a first upper semiconductor layer over a first lower semiconductor layer, and the second semiconductor layer stack having a second upper semiconductor layer over a second lower semiconductor layer;
forming a first source/drain feature coupled to the first upper semiconductor layer and the first lower semiconductor layer;
forming a second source/drain feature coupled to the second upper semiconductor layer and the second lower semiconductor layer;
forming a first gate structure disposed adjacent to the first source/drain feature and between the first upper semiconductor layer and the first lower semiconductor layer; and
forming a second gate structure disposed adjacent to the second source/drain feature and between the second upper semiconductor layer and the second lower semiconductor layer,
wherein the first gate structure and the second gate structure have different gate lengths.

11. The method of claim 10, wherein the first semiconductor layer stack and the second semiconductor layer stack have a same width.

12. The method of claim 10, wherein the first source/drain feature comprises p-type dopants, the second source/drain feature comprises n-type dopants, and a gate length of the first gate structure is greater than a gate length of the second gate structure.

13. The method of claim 12, wherein a thickness of the first lower semiconductor layer is less than a thickness of the second upper semiconductor layer.

14. The method of claim 10, further comprising:
forming a first inner spacer disposed between the first gate structure and the first source/drain feature; and
forming a second inner spacer disposed between the second gate structure and the second source/drain feature.

15. The method of claim 14, wherein the first inner spacer and the second inner spacer have different widths.

16. The method of claim 14, further comprising:
forming a dielectric layer between the first semiconductor layer stack and the second semiconductor layer stack,
wherein the dielectric layer, the first inner spacer, and the second inner spacer have a same composition.

17. A semiconductor device, comprising:
a substrate;
a lower source/drain feature disposed over the substrate;
a first plurality of nanostructures coupled to the lower source/drain feature;
a first gate structure wrapping around each of the first plurality of nanostructures;
an upper source/drain feature over the lower source/drain feature;
a second plurality of nanostructures coupled to the upper source/drain feature; and
a second gate structure wrapping around each of the second plurality of nanostructures,
wherein the first gate structure and the second gate structure have different gate lengths.

18. The semiconductor device of claim 17, wherein the lower source/drain feature comprises p-type dopants, the upper source/drain feature comprises n-type dopants, and a gate length of the first gate structure is greater than a gate length of the second gate structure.

19. The semiconductor device of claim 18, further comprising:
a first inner spacer disposed between the first gate structure and the lower source/drain feature; and
a second inner spacer disposed between the second gate structure and the upper source/drain feature,
wherein the first inner spacer and the second inner spacer have different widths.

20. The semiconductor device of claim 19, wherein a thickness of each of the first plurality of nanostructures is different than a thickness of each of the second plurality of nanostructures.
